(19) United States
(12) Patent Application Publication
(10) Pub. No.: US 2026/0190425 A1
(43) Pub. Date: Jul. 2, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Gerben DOORNBOS, Leuven (BE); Marcus Johannes Henricus VAN DAL, Linden (BE); Viraj Nilesh MADHIWALA, Leuven (BE); Georgios VELLIANITIS, Heverlee (BE)

(21) Appl. No.: 19/012,151

(22) Filed: Jan. 7, 2025

(30) Foreign Application Priority Data
Dec. 27, 2024 (GR) 20240100924

(51) Int. Cl. H10D 64/23; H10D 30/01; H10D 30/62; H10D 64/01

(52) U.S. Cl. CPC H10D 64/258; H10D 30/024; H10D 30/6219; H10D 64/017

(57) ABSTRACT

A fin-based transistor includes a gate structure that is vertically-arranged with source/drain regions of the fin-based transistor. The gate structure may wrap around the top and sides of a fin structure of the fin-based transistor, and source/drain regions of the fin-based transistor are located on a bottom of the fin structure. Source/drain contacts of the fin-based transistor are located on the source/drain regions over the bottom of the fin structure. This enables the gate structure and the source/drain contacts to be located on vertically opposing sides of the fin structure, thereby enabling gate spacers to be omitted from the fin-based transistor.

### CROSS-REFERENCE TO RELATED APPLICATION

This Patent Application claims priority to Greece Patent Application No. 20240100924, filed on Dec. 27, 2024, and entitled “SEMICONDUCTOR DEVICE AND METHODS OF FORMATION.” The disclosure of the prior Application is considered part of and is incorporated by reference into this Patent Application.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source/drain regions (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 2B, 3, 4A, 4B, 5, 6A-6C, and 7A-7I illustrate example implementations of forming a fin-based transistor structure described herein.

FIGS. 8A-8E are diagrams of example implementations of source/drain region arrangements for a semiconductor device described herein.

FIGS. 9A-9E are diagrams of an example implementation of forming a semiconductor device described herein.

FIGS. 10A-10E are diagrams of an example implementation of forming a semiconductor device described herein.

FIGS. 11A-11D are diagrams of an example implementation of forming a semiconductor device described herein.

FIGS. 12A-12C are diagrams of an example implementation of forming a semiconductor device described herein.

FIG. 13 is a flowchart of an example process associated with forming a semiconductor device described herein.

FIG. 14 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a fin-based transistor may include gate spacers between a gate structure of the fin-based transistor and the source/drain contacts of the fin-based transistor. The gate spacers are included to provide electrical isolation and/or to facilitate patterning of various layers and/or structures of the fin-based transistor. However, the gate spacers can be a source of parasitic capacitance between the gate structure and the source/drain contacts, leading to reduced switching speeds (e.g., because of an increased resistance-capacitance (RC) time constant) for the fin-based transistor. Moreover, the gate spacers account for approximately 25% or greater of the overall size of the fin-based transistor. As a result, the gate spacers pose a challenge to reducing the overall side of the fin-based transistor as semiconductor processing nodes advance.

In some implementations described herein, a fin-based transistor includes a gate structure that is vertically-arranged with source/drain regions of the fin-based transistor. The gate structure may wrap around the top and sides of a fin structure of the fin-based transistor, and source/drain regions of the fin-based transistor may be located on a bottom of the fin structure. Source/drain contacts of the fin-based transistor are located on the source/drain regions over the bottom of the fin structure. This enables the gate structure and the source/drain contacts to be located on vertically opposing sides of the fin structure, thereby enabling gate spacers to be omitted from the fin-based transistor. In this way, parasitic capacitance in the fin-based transistor is reduced, and further size reductions for the fin-based transistor can be realized. Additionally and/or alternatively, vertically stacking the gate structure and the source/drain regions of the fin-based transistor enable front-side and back-side connections to be formed for the fin-based transistor. This enables multiple layers of fin-based transistors to be vertically stacked and interconnected to realize complementary metal-oxide-semiconductor (CMOS) logic circuitry and/or to achieve greater fin-based transistor density in a semiconductor device.

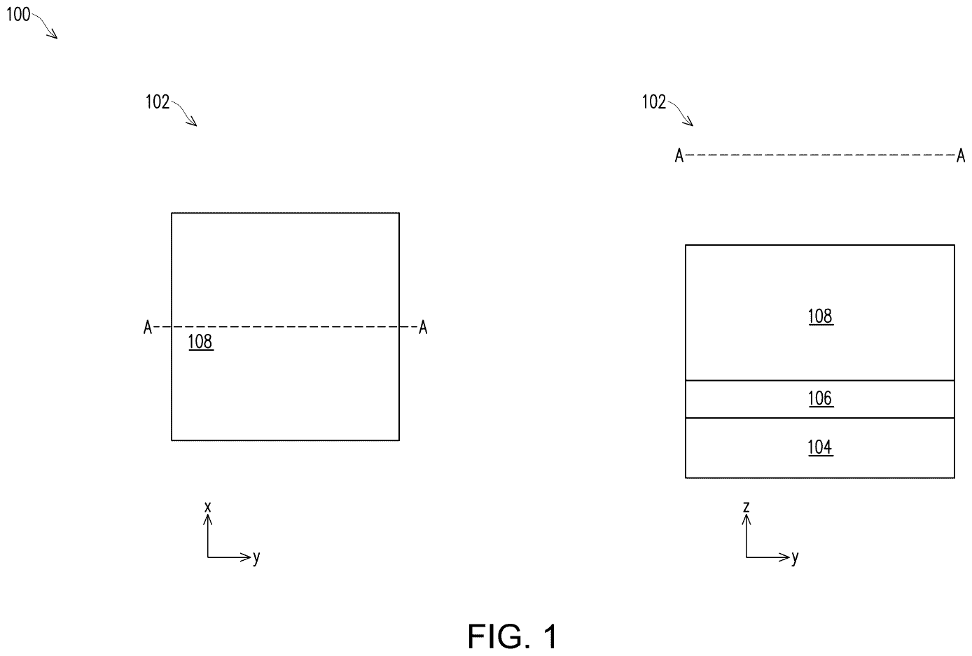

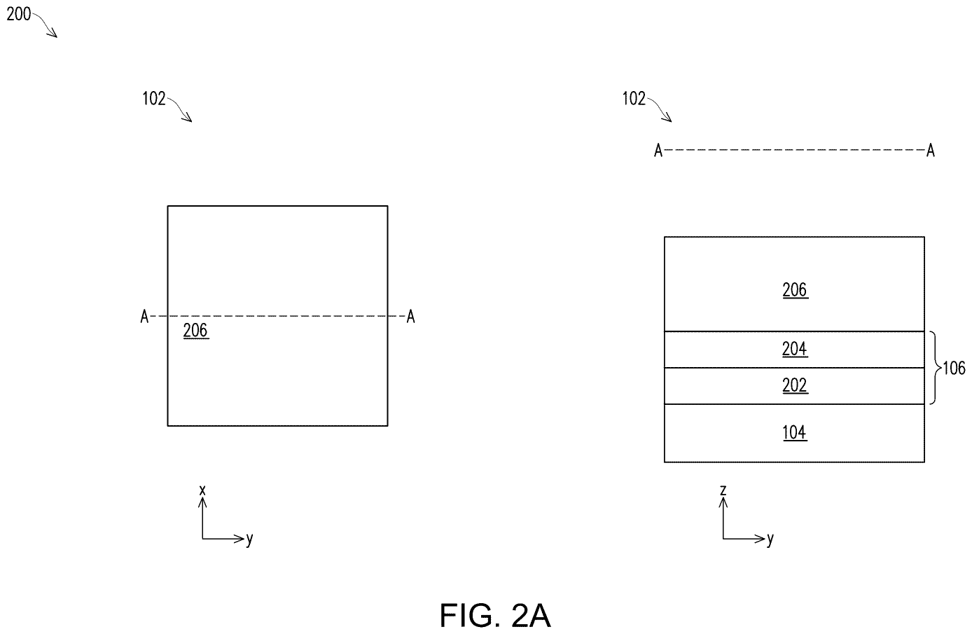

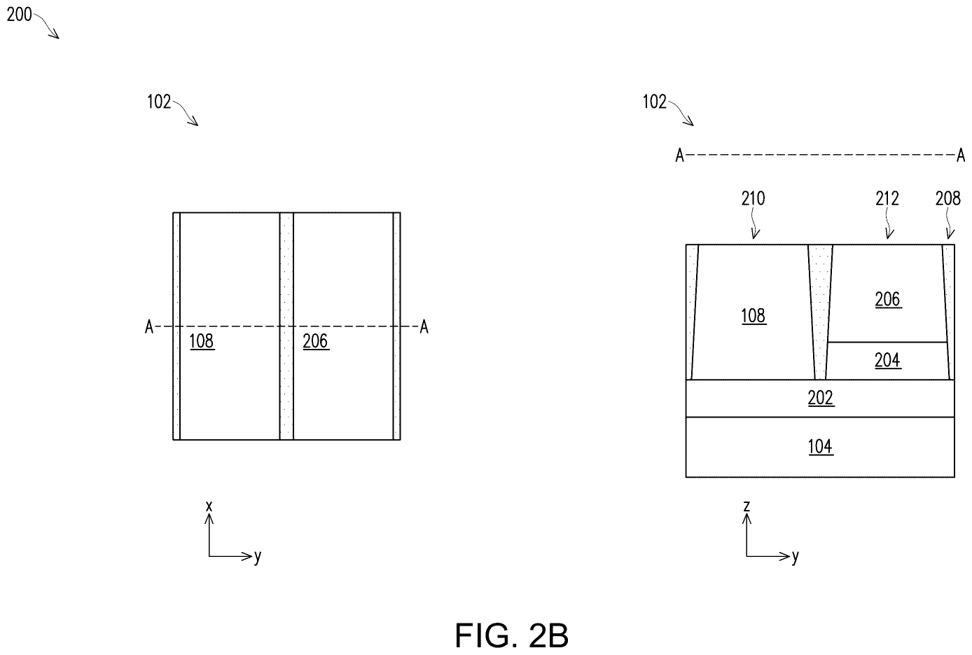

FIGS. 1, 2A, 2B, 3, 4A, 4B, 5, 6A-6C, and 7A-7I illustrate example implementations of forming a fin-based transistor structure described herein. FIG. 1 and FIGS. 2A and 2B are alternative implementations of forming semiconductor layers of a semiconductor device in which the fin-based transistor is to be formed. The alternative implementations are illustrated from top views in an x-y plane and cross-section views in a y-direction along line A-A in FIGS. 1, 2A, and 2B.

As shown in an example implementation 100 in FIG. 1, forming semiconductor layers of a semiconductor device 102 may include providing a semiconductor substrate 104, forming an etch stop layer (e.g., a semiconductor etch stop layer) 106 over and/or on the semiconductor substrate 104, and forming a semiconductor layer 108 over and/or on the etch stop layer 106.

The semiconductor substrate 104 may be provided as a semiconductor die, a semiconductor wafer, and/or another type of semiconductor workpiece. The semiconductor substrate 104, the etch stop layer 106, and the semiconductor layer 108 may each include a semiconductor material such as silicon (Si), doped silicon, germanium (Ge), silicon germanium (SiGe), and/or another type of semiconductor material. In some implementations, the semiconductor substrate 104 and the semiconductor layer 108 include a first semiconductor material such as silicon, and the etch stop layer 106 includes a second semiconductor material such as silicon germanium. This enables the etch stop layer 106 to function as an etch stop when etching the semiconductor layer 108, or removing the semiconductor substrate 104.

A deposition tool may be used to deposit the etch stop layer 106 and/or the semiconductor layer 108 by epitaxy. A deposition technique such as chemical vapor deposition (CVD), physical vapor deposition (PVD), and/or atomic layer deposition (ALD) may be used to deposit the etch stop layer 106 and/or the semiconductor layer 108.

In some implementations, the epitaxy operation may be performed at a low temperature, such as below approximately 350 degrees to minimize and/or avoid intermixing between the germanium of the etch stop layer 106 and the silicon of the semiconductor substrate 104 and of the semiconductor layer 108. Silicon precursors such as disilane (Si₂H₆), trisilane (Si₃H₈), and/or tetrasilane (Si₄H₁₀) may be used to deposit the etch stop layer 106 and/or the semiconductor layer 108. Germanium precursors such as digermane (Ge₂H₆) may be used to deposit the etch stop layer 106.

In some implementations, the etch stop layer is formed to a thickness that is included in a range of approximately 20 nanometers to approximately 200 nanometers. However, other values and ranges are within the scope of the present disclosure. In some implementations, the etch stop layer 106 is formed to include a germanium concentration that is included in a range of approximately 10% by atomic volume to approximately 40% by atomic volume. However, other values and ranges are within the scope of the present disclosure.

In some implementations, the semiconductor layer 108 is formed to a thickness that is included in a range of approximately 30 nanometers to approximately 60 nanometers. However, other values and ranges are within the scope of the present disclosure. In some implementations, an ion implantation tool is used to implant ions into the semiconductor layer 108 to dope the semiconductor layer 108 with one or more types of dopants such as p-type dopants (e.g., boron (B)) and/or n-type dopants (e.g., phosphorous (P) and/or arsenic (As)). In some implementations, the dopant concentration of the semiconductor layer 108 may be included in a range of approximately 1×10¹⁵ atoms per cubic centimeter to approximately 1×10¹⁹ atoms per cubic centimeter. However, other values and ranges are within the scope of the present disclosure.

Alternatively, and as shown in an example implementation 200 in FIG. 2A, the etch stop layer 106 may be formed as a composite etch stop layer that includes a first type semiconductor etch stop layer 202 and a second type semiconductor etch stop layer 204. A first type semiconductor layer 206 may be formed over the etch stop layer 106. The first type semiconductor layer 206 may be a same type of semiconductor material as the first type semiconductor etch stop layer 202.

As shown in FIG. 2B, shallow trench isolation (STI) regions 208 may be formed above the first type etch stop layer 202 so that the STI regions 208 define a first type transistor region 210 and a second type transistor region 212. The first type transistor region 210 may be a region of the semiconductor device 102 in which n-type transistors are to be formed, whereas the second type transistor region 212 may be a region of the semiconductor device 102 in which p-type transistors are to be formed. In the first type transistor region 210, the second type etch stop layer 204 and the first type semiconductor layer 206 may be removed (e.g., by etching using an etch tool and/or by another type of material removal process) and replaced with the semiconductor layer 108 (e.g., a second type semiconductor layer that includes a same semiconductor material as the second type etch stop layer 204). The semiconductor layer 108 may be epitaxially grown on the first type etch stop layer 202.

The first type etch stop layer 202 may have a germanium concentration that is different from the germanium concentration of the first type semiconductor layer 206 to enable the first type semiconductor layer 206 to be selectively etched with minimal etching to the first type etch stop layer 202. In some implementations, the second type etch stop layer 204 is formed to a thickness that is included in a range of approximately 2 nanometers to approximately 8 nanometers. However, other values and ranges are within the scope of the present disclosure.

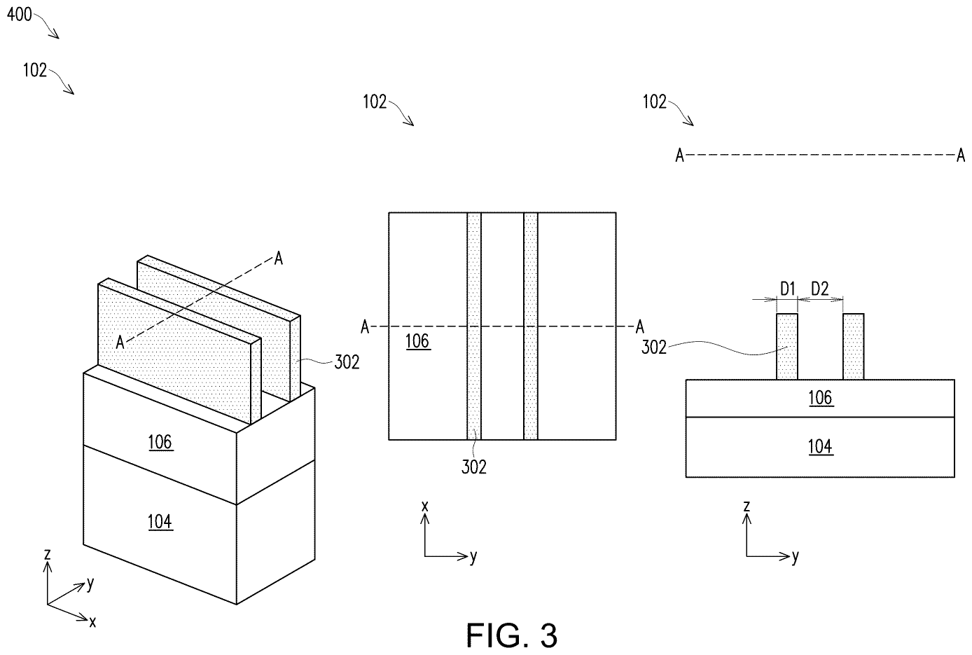

FIG. 3 illustrates an example implementation 300 of a fin formation process described herein, and includes a perspective view, a top view in the x-y plane, and a cross-section view in the y-direction along the line A-A. As shown in FIG. 3, one or more fin structures 302 may be formed from the semiconductor layer 108. Additionally and/or alternatively, one or more fin structures 302 may be formed from the first type semiconductor layer 206.

The fin structure(s) 302 are semiconductor protruding structures that extend above the semiconductor substrate 104 in the z-direction, and that may extend in (and may be elongated in) in the x-direction in the semiconductor device 102. If a plurality of fin structures 302 are formed, the fin structures 302 may be arranged in the y-direction. Alternatively, another type of semiconductor protruding structures may be included in the semiconductor device 102, such as a protruding layer stacks of nanostructure semiconductor layers (e.g., silicon layers and silicon germanium layers). These layer stacks may be processed to form nanostructure transistors, such as gate all around (GAA) transistors, nanosheet transistors, nanowire transistors, and/or other types of nanostructure transistors.

In some implementations, a pattern in a photoresist layer is used to etch the semiconductor layer 108 to form the fin structure(s) 302. In these implementations, a deposition tool may be used to form the photoresist layer on the semiconductor layer 108 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 108 based on the pattern to form the fin structure(s) 302. In some implementations, a photoresist removal tool may be used to remove the remaining portions of the photoresist layer (e.g., using a chemical stripper, plasma ashing, and/or another technique).

In some implementations, the etch operation includes a dry etch operation (e.g., a plasma-based etch operation, a gas-based etch operation), a wet chemical etch operation, and/or another type of etch operation. The etch operation may stop on the etch stop layer 106. Alternatively, a portion of the etch stop layer 106 may be removed in the etch operation.

In some implementations, a hard mask layer is used as an alternative technique for etching the semiconductor layer 108 based on a pattern. In some implementations, patterning techniques, such as double patterning, triple patterning, quadruple patterning, self-aligned double patterning, and/or self-aligned quadruple patterning may be used to form the fin structures 302.

In some implementations, a fin structure 302 is formed to a width (indicated in FIG. 3 as dimension D1) that is included in a range of approximately 4 nanometers to approximately 10 nanometers. However, other values and ranges are within the scope of the present disclosure. In some implementations, fin structures 302 are formed at a pitch (indicated in FIG. 3 as dimension D2) that is included in a range of approximately 20 nanometers to approximately 50 nanometers. However, other values and ranges are within the scope of the present disclosure.

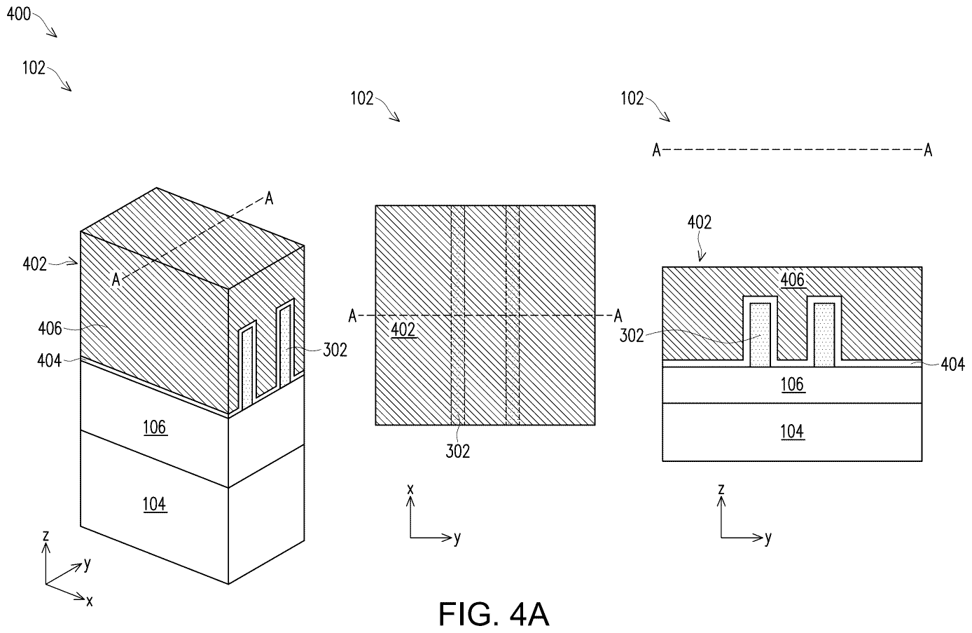

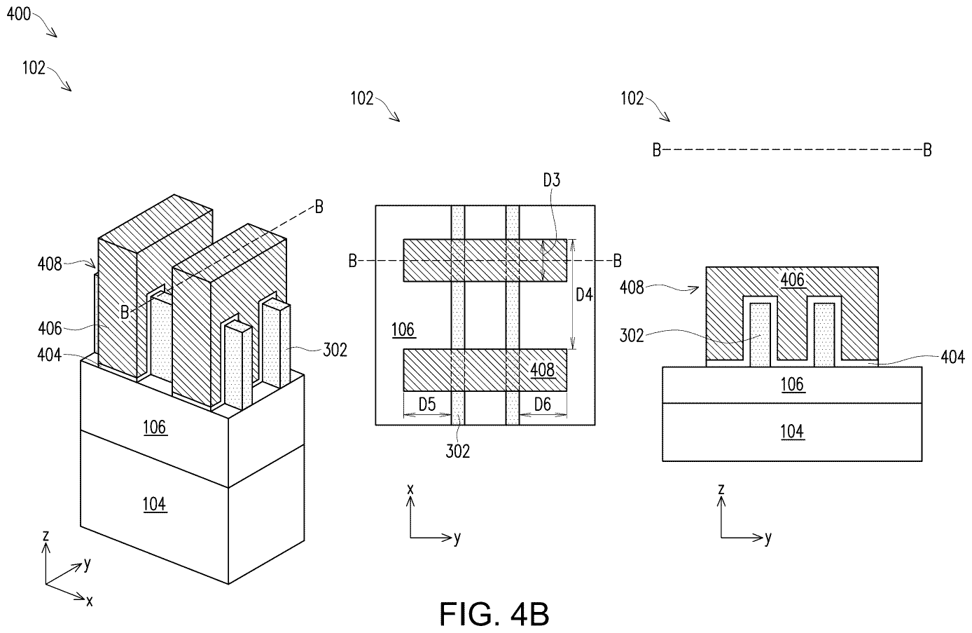

FIGS. 4A and 4B illustrate an example implementation 400 of a dummy gate formation process described herein, and include a perspective view, a top view in the x-y plane, and a cross-section view in the y-direction along the line A-A. As shown in FIG. 4A, a dummy gate stack 402 is formed over the fin structures 302. The dummy gate stack 402 may include a dummy dielectric layer 404 that is formed over and/or on a front side of the semiconductor device 102 such that the dummy dielectric layer 404 is formed on the sidewalls and top surface of the fin structure(s) 302. The front side of the semiconductor device 102 is the side of the semiconductor substrate 104 on which the fin structure(s) 302 are formed. The tops of the fin structure(s) 302 are the parts of the fin structure(s) 302 distal from the semiconductor substrate 104 in the z-direction. The bottoms of the fin structure(s) 302 are the parts of the fin structure(s) 302 proximate to the semiconductor substrate 104 in the z-direction.

The dummy dielectric layer 404 may include one or more dielectric materials such as silicon oxide (SiOₓ such as SiO₂) and/or silicon nitride (SiₓN_{y} such as Si₃N₄), among other examples. A deposition tool may be used to deposit the dummy dielectric layer 404 using a PVD technique, an ALD technique, a CVD technique, an epitaxy technique, an oxidation technique, and/or another suitable deposition technique. In some implementations, the dummy dielectric layer 404 is formed to a thickness that is included in a range of approximately 1 nanometer to approximately 4 nanometers. However, other values and ranges are within the scope of the present disclosure.

As further shown in FIG. 4A, the dummy gate stack 402 may include a dummy electrode layer 406 that is formed on the front side of the semiconductor device 102 such that the dummy electrode layer 406 is formed over and/or on the dummy dielectric layer 404. The dummy electrode layer 406 may include polysilicon and/or another suitable material.

The dummy electrode layer 406 may be blanket deposited such that the dummy electrode layer 406 covers the fin structure(s) 302. A deposition tool may be used to deposit the dummy electrode layer 406 using a PVD technique, an ALD technique, a CVD technique, an epitaxy technique, an oxidation technique, and/or another suitable deposition technique. In some implementations, a planarization tool may be used to perform a planarization operation (e.g., a chemical-mechanical planarization (CMP) operation) to planarize the dummy electrode layer 406. In some implementations, the dummy electrode layer 406 is formed to a thickness that is included in a range of approximately 40 nanometers to approximately 200 nanometers. However, other values and ranges are within the scope of the present disclosure.

As shown in FIG. 4B, the dummy dielectric layer 404 and the dummy electrode layer 406 may be etched to define one or more dummy gate structures 408 of the semiconductor device 102. A dummy gate structure 408 is a temporary gate structure that is formed as a placeholder for a gate structure (e.g., a metal gate structure) of a transistor of the semiconductor device 102. The dummy gate structure 408 temporarily occupies a space for the gate structure and acts as a sacrificial structure during formation of other layers and/or structures of the semiconductor device 102. In this way, eventual damage arising from these processes is absorbed by the dummy gate structure 408 as opposed to the gate structures of the transistors, thereby minimizing the damage to the gate structures.

A dummy gate structure 408 extends in the y-direction in the semiconductor device and wraps around the tops and sides of the fin structure(s) 302. In some implementations, a dummy gate structure 408 fully wraps around four sides of a fin structure 302. In implementations in which a plurality of dummy gate structures 408 are formed, the dummy gate structures 408 may be arranged in the x-direction. In this way, the dummy gate structures 408 extend in an approximately orthogonal direction to the fin structure(s) 302, such that the dummy gate structures 408 cross over one or more fin structures 302.

In some implementations, a pattern in a photoresist layer is used to etch the dummy dielectric layer 404 and the dummy electrode layer 406 to form the dummy gate structure(s) 408. In these implementations, a deposition tool may be used to form the photoresist layer on the dummy electrode layer 406 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dummy dielectric layer 404 and the dummy electrode layer 406 based on the pattern to form the dummy gate structure(s) 408. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the dummy gate structures 408 based on a pattern.

As shown in FIG. 4B, a dummy gate structure 408 may have a gate length (indicated in FIG. 4B as dimension D3) that is included in a range of approximately 10 nanometers to approximately 40 nanometers. However, other values and ranges are within the scope of the present disclosure. A pitch between adjacent dummy gate structures 408 (indicated in FIG. 4B as dimension D4) may be included in a range of approximately 28 nanometers to approximately 56 nanometers. However, other values and ranges are within the scope of the present disclosure. In some implementations, opposing ends of a dummy gate structure 408 may extend laterally outward from fin structures 302 by approximately the same distance. In some implementations, opposing ends of a dummy gate structure 408 may extend laterally outward from fin structures 302 asymmetrically such that a first distance of a first end (indicated in FIG. 4B as dimension D5) and a second distance of a second end (indicated in FIG. 4B as dimension D6) are different distances.

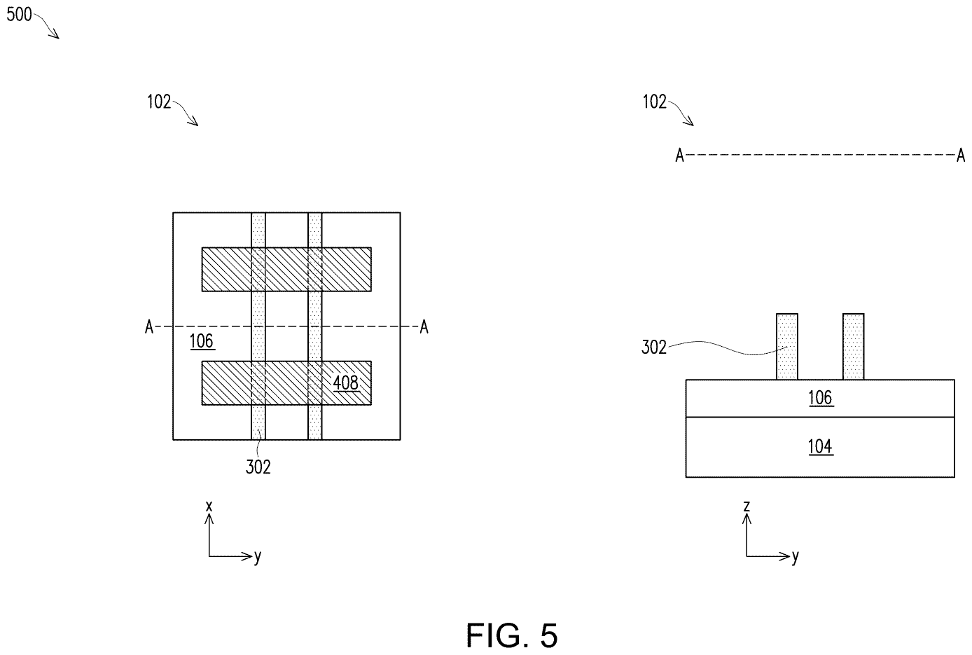

FIG. 5 illustrates an example implementation 500 of a fin doping process described herein, and includes a top view in the x-y plane and a cross-section view in the y-direction along the line A-A. As shown in FIG. 5, an ion implantation operation may be performed to dope one or more of the fin structures 302 with one or more types of dopants. In some implementations, a fin structure 302 for an n-type transistor may be doped with n-type dopants such as arsenic (As) and/or phosphorous (P), among other examples. In some implementations, a fin structure 302 for a p-type transistor may be doped with p-type dopants such as boron (B), indium (In), and/or gallium (Ga), among other examples. In some implementations, a fin structure 302 may be doped to have a dopant concentration that is included in a range of approximately 1×10¹⁹ atoms per cubic centimeter to approximately 1×10²¹ atoms per cubic centimeter. However, other values and ranges are within the scope of the present disclosure.

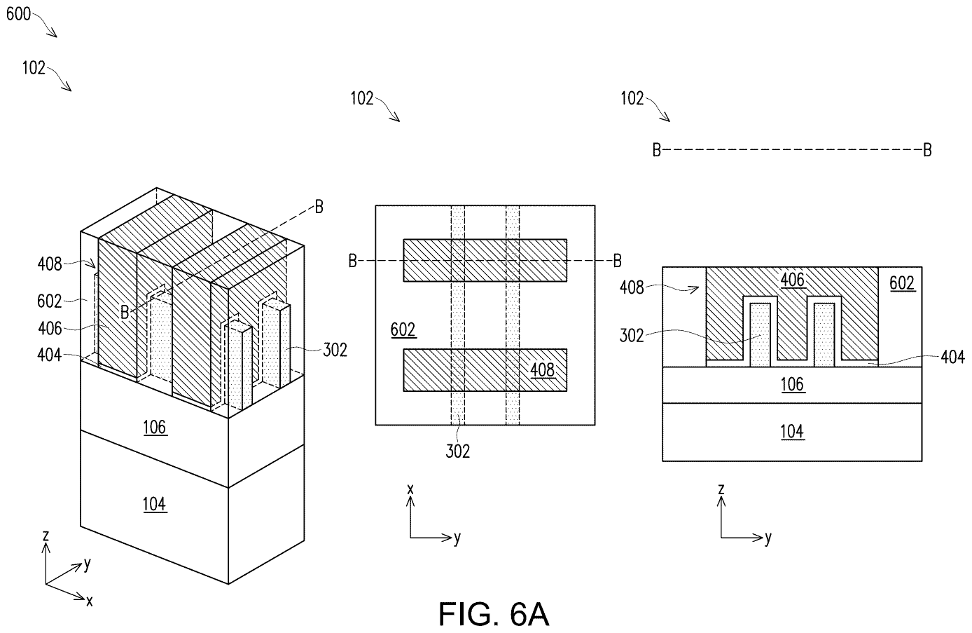

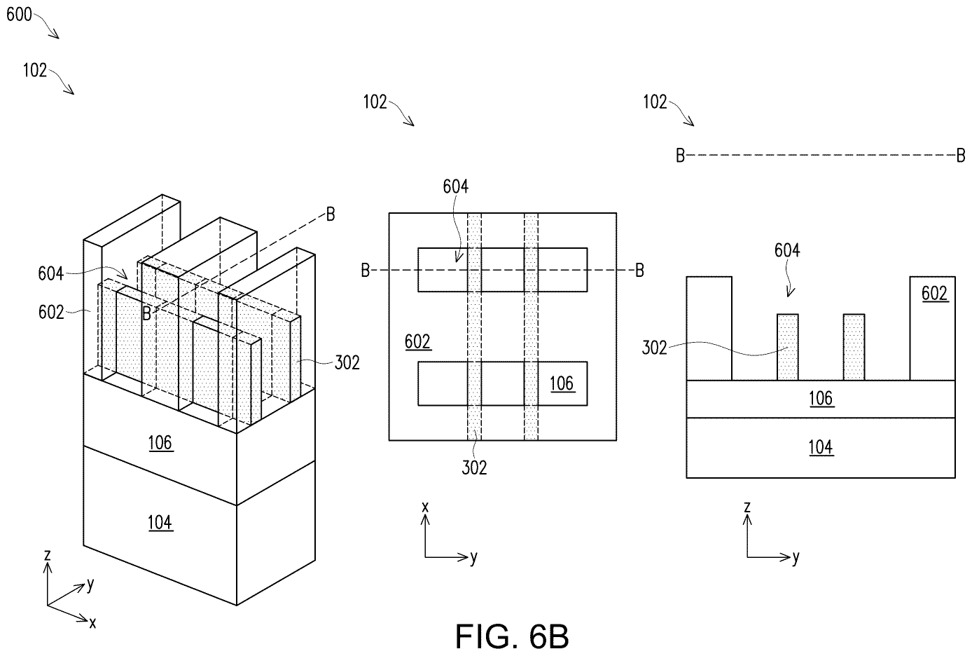

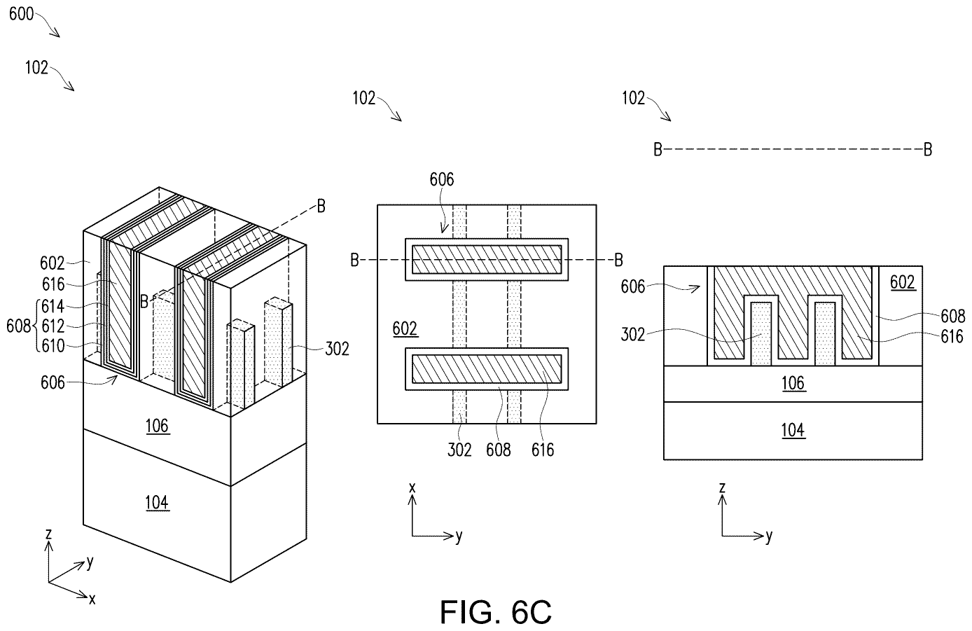

FIGS. 6A-6C illustrate an example implementation 600 of replacement gate process described herein, and include a perspective view, a top view in the x-y plane, and a cross-section view in the y-direction along the line B-B. The line B-B is along a dummy gate structure 408 in the y-direction. As shown in FIGS. 6A-6C, the replacement gate process includes replacing the dummy gate structures 408 with gate structures (e.g., metal gate structures) of the transistors of the semiconductor device 102.

As shown in FIG. 6A, an interlayer dielectric (ILD) layer 602 may be deposited around the dummy gate structures 408. In some implementations, the ILD layer 602 is deposited such that the ILD layer 602 covers the dummy gate structures 408, and a planarization tool is used to perform a planarization operation (e.g., a CMP operation) such that the tops of the dummy gate structures 408 are exposed and such that the top of the ILD layer 602 is approximately co-planar with the tops of the dummy gate structure 408.

The ILD layer 602 may include one or more dielectric materials such as silicon oxide (SiOₓ such as SiO₂) and/or silicon nitride (SiₓN_{y} such as Si₃N₄), among other examples. A deposition tool may be used to deposit the ILD layer 602 using a PVD technique, an ALD technique, a CVD technique, an epitaxy technique, an oxidation technique, and/or another suitable deposition technique.

As shown in FIG. 6B, one or more etch operations may be performed to remove the dummy gate structures 408. This leaves behind openings 604 in which portions of the fin structures 302 are exposed.

As shown in FIG. 6C, gate structures 606 are formed in the openings 604 left behind by removal of the dummy gate structures 408. Thus, the gate structures 606 are formed on the front side of the semiconductor device 102 such that the gate structures 606 wrap around the tops and sidewalls of the fin structures 302. The gate structures 606 may extend in the y-direction and may be arranged in the x-direction. In some implementations, a gate structure 606 may extend across a plurality of fin structures 302.

A gate structure 606 may include a conformal layer stack 608 that conforms to the profile of the fin structures 302. The conformal layer stack 608 may include an interfacial layer 610, a gate dielectric layer 612, and/or a work function metal layer 614, among other examples. A gate structure may further include a gate electrode layer 616 that fills in the remaining areas of the openings 604.

The interfacial layer 610 may include an oxide layer that is formed from a chemical reaction with the surface of the fin structures 302. For example, a chemical oxidation process using ozone (O₃) in combination with hydrofluoric acid (HF) and/or hydrochloric acid (HCl) may be used to oxidize the exposed portions of the fin structures 302 in the openings 604 to form the interfacial layer 610.

Additionally and/or alternatively, the interfacial layer 610 may be formed by a thermal oxidation process, such as by rapid thermal anneal (RTA). The semiconductor device 102 may be placed in a processing chamber, and an oxygen-containing gas may be provided into the processing chamber for the RTA process. In some implementations, an in-situ steam generation (ISSG) technique is used for the thermal oxidation process.

In some implementations, the interfacial layer 610 is formed by deposition, and a deposition tool may be used to deposit the interfacial layer 610 using an ALD technique, a CVD technique, and/or another suitable deposition technique.

In some implementations, the interfacial layer 610 is formed to a thickness that is included in a range of approximately 0.2 nanometers to approximately 2 nanometers. However, other values and ranges are within the scope of the present disclosure. After the interfacial layer 610 is formed, an anneal may be performed in a hydrogen-containing environment and/or with a hydrogen-based plasma to passivate dangling bonds at the interface between the interfacial layer 610 and the fin structures 302.

The gate dielectric layer 612 may include a high dielectric constant (high-k) dielectric material having a dielectric constant that is greater than approximately 3.9. Such high-k dielectric materials may include hafnium oxide (HfOₓ such as HfO₂), aluminum oxide (AlₓO_{y} such as Al₂O₃), zirconium oxide (ZrOₓ such as ZrO₂), hafnium zirconium oxide (HfZrOₓ), hafnium silicon oxide (HfSiOₓ), lanthanum oxide (LaₓO_{y} such as La₂O₃), and/or titanium oxide (TiOₓ such as TiO₂), among other examples. Additionally and/or alternatively, the gate dielectric layer 612 may include one or more low dielectric constant (low-k) dielectric materials such as silicon oxide (SiOₓ such as SiO₂).

In some implementations, the gate dielectric layer 612 is formed by deposition, and a deposition tool may be used to deposit the gate dielectric layer 612 using an ALD technique, a CVD technique, and/or another suitable deposition technique. In some implementations, the gate dielectric layer 612 is formed to a thickness that is included in a range of approximately 1 nanometer to approximately 4 nanometers. However, other values and ranges are within the scope of the present disclosure.

After the gate dielectric layer 612 is deposited, an anneal may be performed on the gate dielectric layer 612 to cure bulk defects in the gate dielectric layer 612. The anneal may be performed in an environment that contains hydrogen gas, oxygen gas, and/or nitrogen gas, among other examples.

The work function metal layer 614 may include one or more metals and/or one or more metal alloys that are included for tuning the work function of the gate structure 606. In some implementations, a work function metal layer 614 of an n-type transistor may include an n-type metal that tunes or adjusts the work function of the gate structure 606 of the n-type transistor near the conduction band of the material of the fin structure(s) 302. Examples of such n-type metals include titanium aluminum (TiAl), titanium aluminum carbon (TiAlC), and/or another aluminum-containing metal, among other examples. In some implementations, a work function metal layer 614 of a p-type transistor may include one or more p-type metals, such as titanium nitride (TiN), tungsten nitride (WN), and/or another metal having a work function that is greater than approximately 4.7 eV, among other examples. The p-type metal may be included to tune the work function of the p-type transistor such that the work function is adjusted close to the valance band of the material of the fin structure(s) 302.

In some implementations, the work function metal layer 614 is formed by deposition, and a deposition tool may be used to deposit the work function metal layer 614 using an ALD technique, a CVD technique, and/or another suitable deposition technique. In some implementations, the work function metal layer 614 is formed to a thickness that is included in a range of approximately 2 nanometers to approximately 8 nanometers. However, other values and ranges are within the scope of the present disclosure.

The gate electrode layer 616 may include one or more metals, such as tungsten (W), titanium (Ti), and/or copper (Cu), among other examples. In some implementations, the gate electrode layer 616 is formed by deposition, and a deposition tool may be used to deposit the gate electrode layer 616 using an ALD technique, a CVD technique, and/or another suitable deposition technique. In some implementations, a planarization tool is used to planarize the gate structures 606 after the gate electrode layer 616 is deposited.

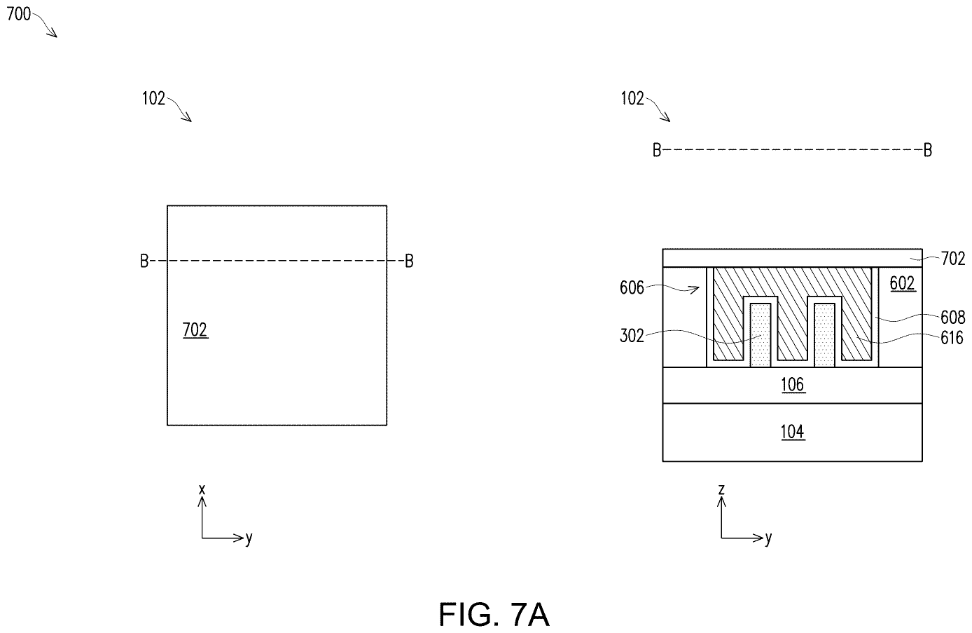

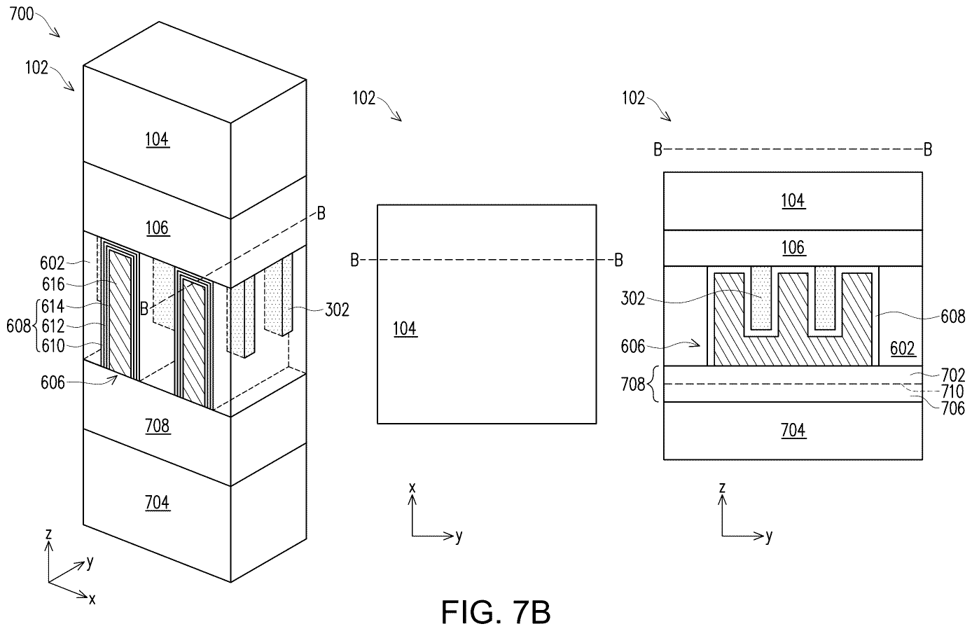

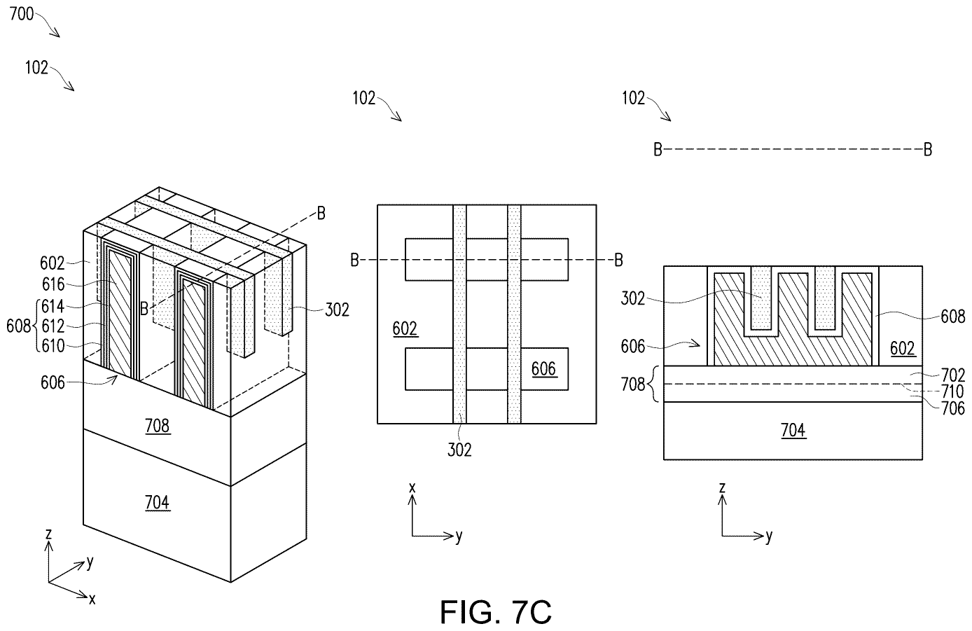

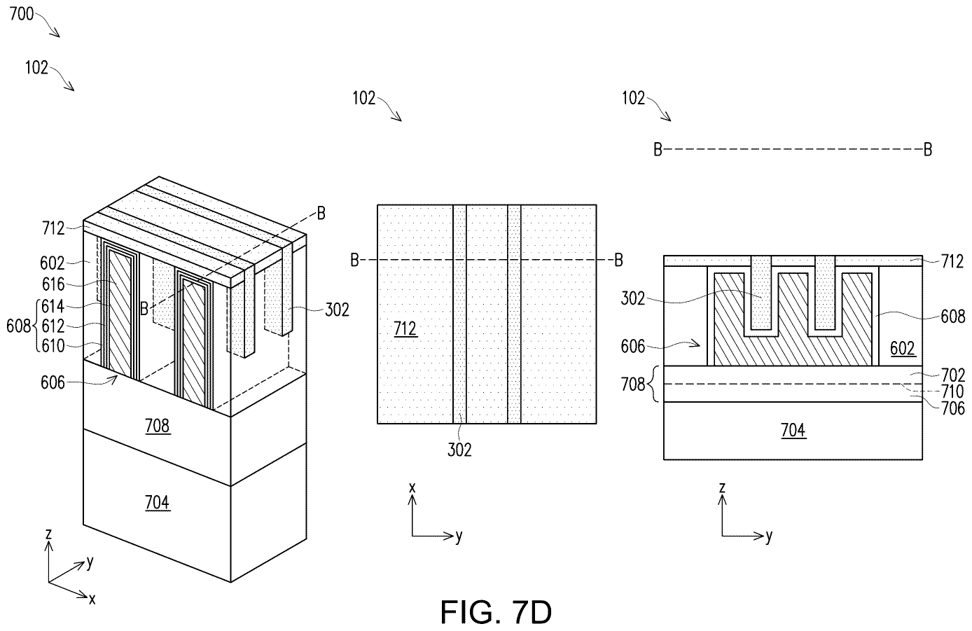

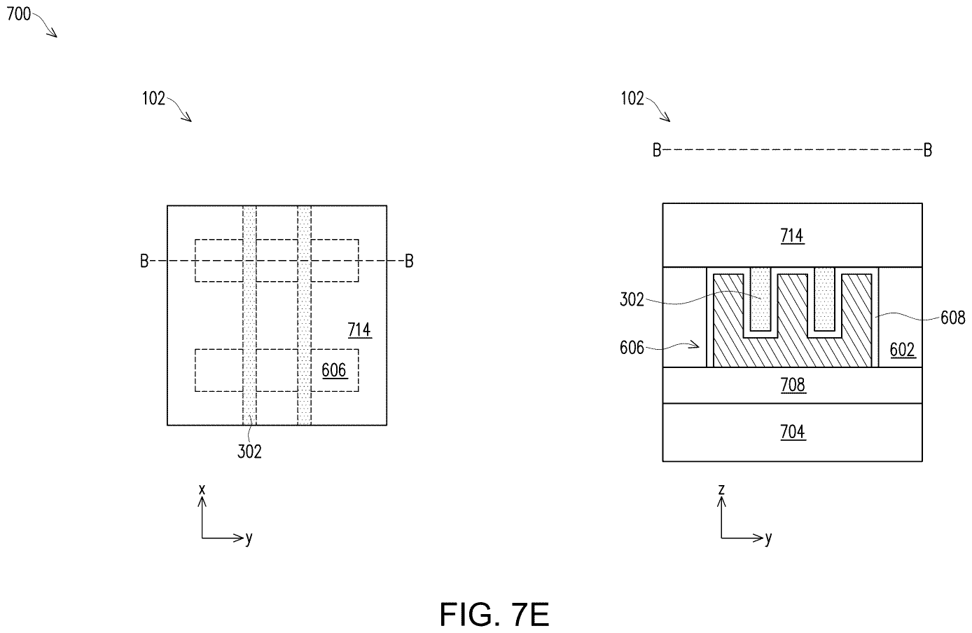

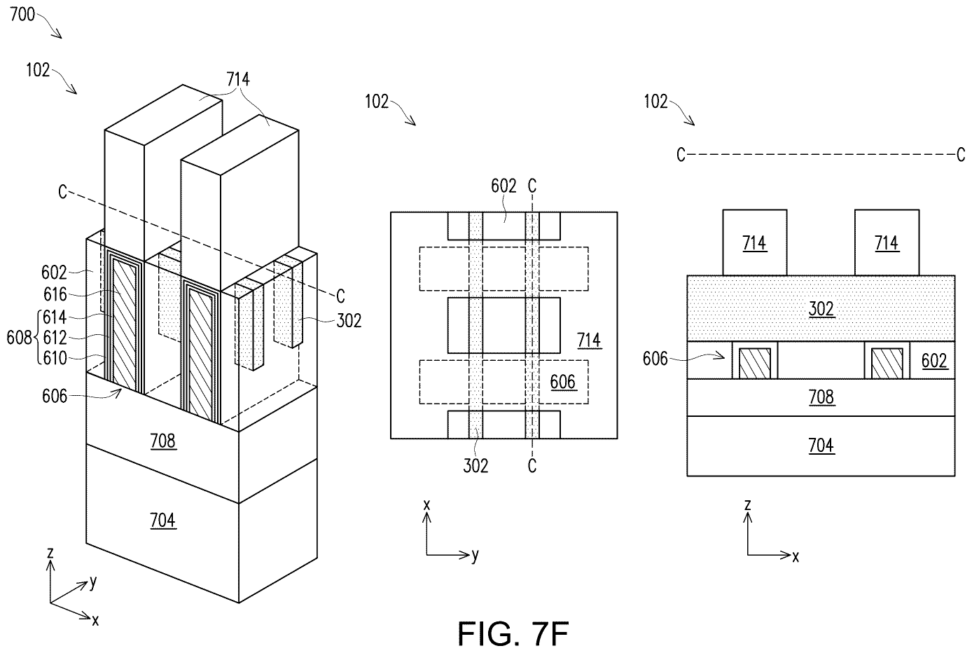

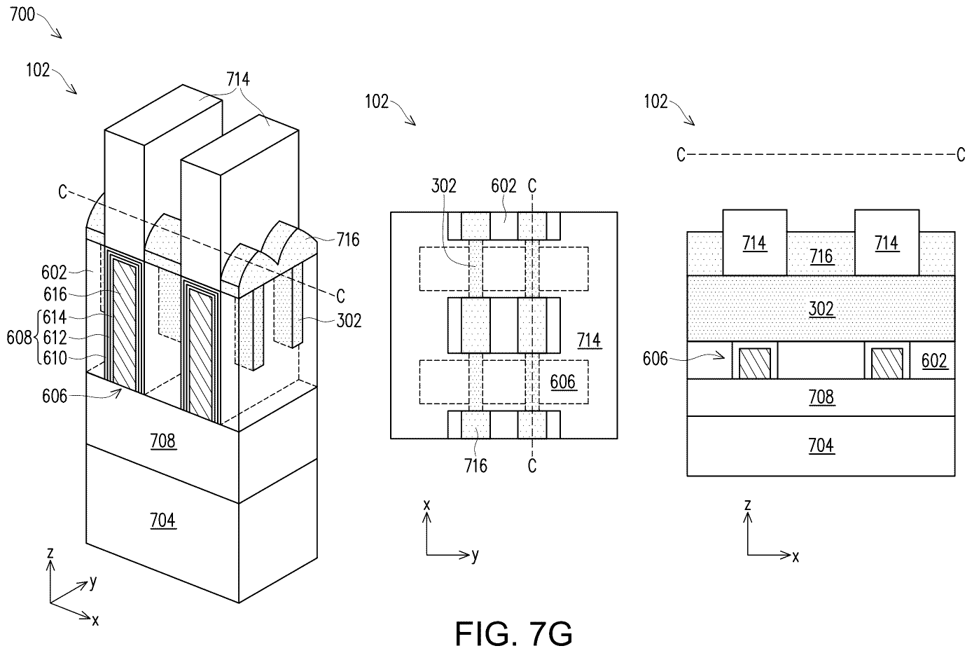

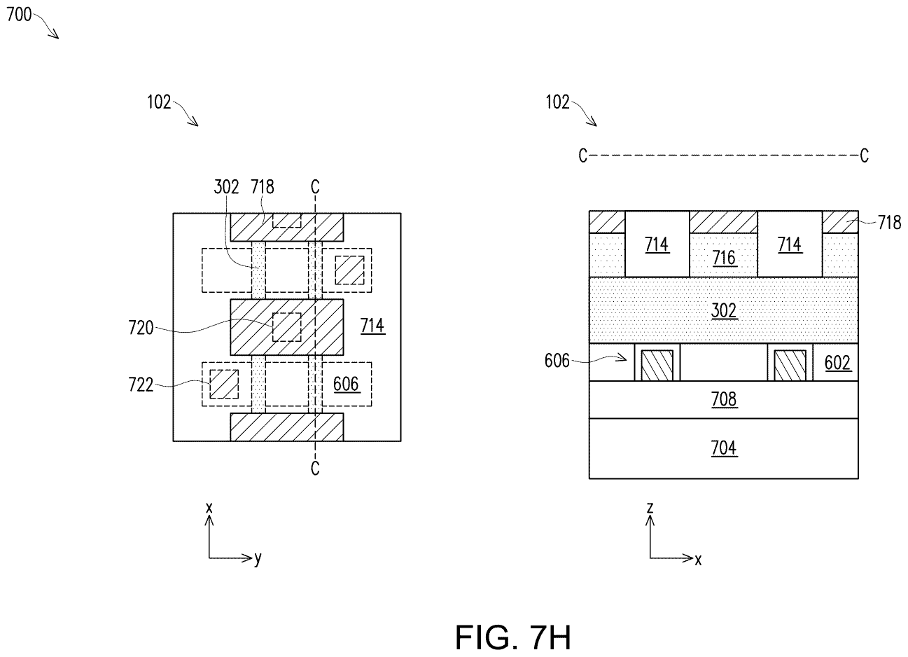

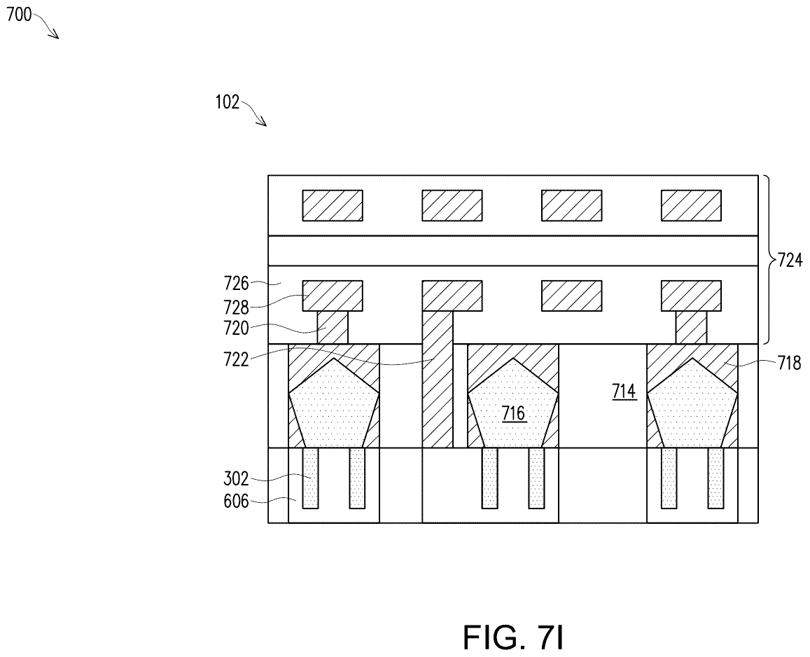

FIGS. 7A-7I illustrate an example implementation 700 of back side processing of the semiconductor device 102 described herein. FIGS. 1, 2A, 2B, 3, 4A, 4B, 5, and 6A-6C illustrate front side process operations for the semiconductor device 102, in which the fin structures 302 and gate structures 606 are formed on the front side of the semiconductor device 102. FIGS. 7A-7I illustrate back side process operations for the semiconductor device 102, in which source/drain regions and source/drain contacts of the transistors of the semiconductor device 102 are formed on the back side of the semiconductor device 102. In this way, the source/drain contacts and the gate structures 606 are located on opposing sides of the fin structures 302 (e.g., the gate structures 606 are located on the front side, or tops, of the fin structures 302, and the source/drain contacts are located on the back side, or bottoms, of the fin structures 302) so that gate spacers can be omitted.

FIGS. 7A-7E include perspective views, top views in the x-y plane, and cross-section views in the y-direction along the line B-B. The line B-B is along a gate structure 606 in the y-direction. FIGS. 7F-7H include perspective views, top views in the x-y plane, and cross-section views in the y-direction along a line C-C. The line C-C is along a fin structure 302 and across a plurality of gate structures the x-direction. FIG. 7I is a composite of superimposed cross-sections in the y-direction, including a cross-section across a plurality of source/drain regions and a cross-section across a plurality of gate structures 606.

As shown in FIGS. 7A and 7B, a bonding layer 702 may be formed on the front side of the semiconductor device 102 so that the bonding layer 702 can be used to bond the front side of the semiconductor device 102 to a carrier substrate 704. To bond the semiconductor device 102 to the carrier substrate 704, a bonding tool may be used to perform a bonding operation to bond the bonding layer 702 on the front side of the semiconductor device 102 to a bonding layer 706 on the carrier substrate 704.

FIG. 7B depicts the semiconductor device 102 after the bonding operation, flipped, with the semiconductor substrate now facing up. As shown in FIG. 7B, the bonding layers 702 and 706 may merge to form a bonding layer 708. In some implementations, a bonding interface 710 between the bonding layers 702 and 706 is visible in the semiconductor device 102. In some implementations, no bonding interface is visible, and the bonding layers 702 and 706 merge into a singular layer.

The bonding layers 702 and 706 may each include one or more dielectric materials, such as silicon oxide (SiOₓ such as SiO₂), silicon nitride (SiₓN_{y} such as Si₃N₄), and/or silicon carbonitride (SiCN), among other examples. A deposition tool may be used to deposit the bonding layers 702 and 706 using an ALD technique, a CVD technique, and/or another suitable deposition technique. In some implementations, a planarization tool is used to planarize the bonding layers 702 and/or 706 after the bonding layers 702 and/or 706 is deposited. In some implementations, a thickness of the bonding layer 702 and/or a thickness of the bonding layer 706 may be included in a range of approximately 10 nanometers to approximately 100 nanometers. However, other values and ranges are within the scope of the present disclosure.

As further shown in FIG. 7B, the semiconductor device 102 is bonded to the carrier substrate 704 such that the front side of the semiconductor device 102 is facing the carrier substrate 704, and such that the back side of the semiconductor device 102 is facing away from the carrier substrate 704. This enables back side processing to be performed on the semiconductor device 102.

As shown in FIG. 7C, back side processing of the semiconductor device 102 may include removing the semiconductor substrate 104 and the etch stop layer 106 from the back side of the semiconductor device 102. In some implementations, an etch tool is used to perform an etch operation to etch the semiconductor substrate 104 and/or the etch stop layer 106 to remove the semiconductor substrate 104 and/or the etch stop layer 106. In some implementations, a planarization tool (e.g., a CMP tool) is used to perform a planarization operation to remove the semiconductor substrate 104 and/or the etch stop layer 106. In some implementations, a planarization tool (e.g., a wafer grinding tool) is used to perform a grinding operation to remove the semiconductor substrate 104 and/or the etch stop layer 106. In some implementations, the etch operation, the planarization operation, and/or the grinding operation is stopped once the bottoms of the fin structures 302 are exposed on the back side of the semiconductor device 102.

FIG. 7D illustrates an alternative to FIG. 7C in which STI regions 712 are included around the fin structures 302. The STI regions 712 may correspond to STI regions 208 in FIG. 2B, and/or may correspond to different STI regions. The STI regions 712 may be formed after formation of the fin structures 302 and prior to formation of the dummy gate structures 408. In these implementations, the etch operation, the planarization operation, and/or the grinding operation is stopped once the STI regions 712 are reached, to prevent removal of material from the gate structures 606.

As shown in FIG. 7E, an ILD layer 714 may be formed over and/or on the back side of the semiconductor device 102. The ILD layer 714 may include one or more dielectric materials such as silicon oxide (SiOₓ such as SiO₂) and/or silicon nitride (SiₓN_{y} such as Si₃N₄), among other examples. In some implementations, the ILD layer 602 and the ILD layer 714 include the same dielectric material. In some implementations, the ILD layer 602 and the ILD layer 714 include different dielectric materials.

A deposition tool may be used to deposit the ILD layer 714 using a PVD technique, an ALD technique, a CVD technique, an epitaxy technique, an oxidation technique, and/or another suitable deposition technique. A planarization tool is used to perform a planarization operation (e.g., a CMP operation) to planarize the ILD layer 714. In some implementations, the ILD layer 714 is formed to a thickness that is included in a range of approximately 40 nanometers to approximately 200 nanometers. However, other values and ranges are within the scope of the present disclosure.

In some implementations, the ILD layer 714 is formed to include a multiple-layer stack. For example, a first dielectric layer of the multiple-layer stack may be formed on the back side of the semiconductor device 102, and a second dielectric layer of the multiple-layer stack may be formed on the first dielectric layer. The first dielectric layer may include a thin film (e.g., having a thickness that is included in a range of approximately 2 nanometers to approximately 8 nanometers) that includes a high-k dielectric material, and the second dielectric layer may include a thick film that includes a low-k dielectric material.

As shown in FIG. 7F, the ILD layer 714 may be patterned and etched to expose portions of the fin structures 302 that are not located under the gate structures 606. For example, the ILD layer 714 may be patterned and etched to expose portions of the fin structures 302 that are located adjacent to a gate structure 606. As another example, the ILD layer 714 may be patterned and etched to expose portions of the fin structures 302 that are located between adjacent gate structures 606.

In some implementations, a pattern in a photoresist layer is used to etch the ILD layer 714 to expose portions of the fin structures 302. In these implementations, a deposition tool may be used to form the photoresist layer on the ILD layer 714 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 714 based on the pattern to expose the portions of the fin structures 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 714 based on a pattern.

As indicated above, the ILD layer 714 may include a multiple-layer stack. The multiple-layer stack enables etching of the ILD layer 714 to be highly controlled, which helps to minimize etching into the underlying fin structures 302. A first etch operation may be performed to etch through the second dielectric layer of the multiple-layer stack, and a second etch operation may be performed to etch through the first dielectric layer of the multiple-layer stack.

As shown in FIG. 7G, source/drain regions 716 of one or more transistors are formed on the back side of the semiconductor device 102. In particular, source/drain regions 716 are formed on the exposed portions of the fin structures 302. Thus, the source/drain regions 716 are formed on the bottoms of the fin structures 302. “Source/drain region(s)” may refer to a source or a drain, individually or collectively, dependent upon the context.

Forming a source/drain region 716 may include epitaxially growing semiconductor material on the exposed portions of the fin structures 302. In some implementations, a source/drain region 716 may be doped with one or more types of dopants. For example, a source/drain region 716 for an n-type transistor may be silicon, doped with n-type dopants such as arsenic (As) and/or phosphorous (P), among other examples. As another example, a source/drain region 716 for a p-type transistor may be silicon or silicon germanium, doped with p-type dopants such as boron (B), indium (In), and/or gallium(Ga), among other examples.

As shown in FIG. 7H, source/drain contacts 718 may be formed on and/or around the source/drain regions 716. The source/drain contacts 718 may include vias, plugs, and/or another type of electrically conductive structures. The source/drain contacts 718 may include tungsten (W), cobalt (Co), ruthenium (Ru), titanium (Ti), titanium nitride (TiN), aluminum (Al), and/or gold (Au), among other electrically conductive materials. A deposition tool may be used to deposit the source/drain contacts 718 using a PVD technique, an ALD technique, a CVD technique, and/or another suitable deposition technique. The source/drain contacts 718 may be deposited in one or more deposition operations. A source/drain contact 718 may be deposited on the top of, and/or around the sides of, a source/drain region 716.

In some implementations, one or more liners may be formed on the sidewalls of the ILD layer 714, and the source/drain contacts 718 may be formed on the sidewalls. The liners may include barrier liners, adhesion liners, and/or another type of liners, and may include materials such as tantalum, tantalum nitride (TaN), titanium nitride (TiN), and/or ruthenium oxide (RuOₓ), among other examples.

In some implementations, a metal silicide layer is formed at the interface between source/drain region 716 and source/drain contact 718, and a source/drain contact 718 is formed on the metal silicide layer. The metal silicide layer may be formed by depositing a layer of metal on the bottom of the fin structure 302, such as a layer of titanium and/or a layer of ruthenium, and performing an annealing operation to cause the layer of metal to diffuse into the surface of the bottom of the fin structure 302.

As further shown in FIG. 7H, source/drain interconnects 720 may be formed on the source/drain contacts 718. The source/drain interconnects 720 may include vias, conductive pillars, conductive columns, and/or another type of electrically conductive structures. The source/drain interconnects may include copper (Cu), tungsten (W), cobalt (Co), ruthenium (Ru), titanium (Ti), aluminum (Al), and/or gold (Au), among other electrically conductive materials. A deposition tool may be used to deposit the source/drain interconnects 720 using a PVD technique, an ALD technique, a CVD technique, and/or another suitable deposition technique.

As further shown in FIG. 7H, gate interconnects 722 may be formed on and/or around the gate structures 606. The gate interconnects 722 may include vias, conductive pillars, conductive columns, and/or another type of electrically conductive structures. The source/drain interconnects may include copper (Cu), tungsten (W), cobalt (Co), ruthenium (Ru), titanium (Ti), aluminum (Al), and/or gold (Au), among other electrically conductive materials. A deposition tool may be used to deposit the gate interconnects 722 using a PVD technique, an ALD technique, a CVD technique, and/or another suitable deposition technique.

As shown in FIG. 7I, in the example implementation 700, the source/drain contacts 718, the source/drain interconnects 720, and the gate interconnects 722 are formed on the back side of the semiconductor device 102. The source/drain interconnects 720, and the gate interconnects 722 may be formed as part of an interconnect layer 724 formed on the back side of the semiconductor device 102. Therefore, the interconnect layer 724 may be referred to as a back side interconnect layer 724 (or a back side back end of line (BEOL) region).

The source/drain interconnects 720 may be formed in an ILD layer 726 of the interconnect layer 724. The gate interconnects 720 may be formed in an ILD layer 726 of the interconnect layer 724 and may extend through the ILD layer 714 to underlying gate structures 606 on the front side of the semiconductor device 102. Therefore, the gate interconnects 720 may extend between the front side and the back side of the semiconductor device.

The source/drain interconnects 720 and the gate interconnects 722 may be electrically connected to conductive structures 728 in the interconnect layer 724. The conductive structures 728 provide electrical routing that enables signals and/or power to be distributed throughout the semiconductor device 102. The conductive structures 728 may include a combination of trenches, metallization layers, conductive traces, vias, interconnects, and/or other types of conductive structures. The conductive structures 728 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In this way, the semiconductor device 102 may include a fin structure 302, a gate structure 606 on a first side of the fin structure 302, a source/drain region 716 on a second side of the fin structure 302 vertically opposing the first side, a source/drain contact 718 on the source/drain region 716 above the second side of the fin structure 302, a source/drain interconnect 720 on the source/drain contact 718 above the second side of the fin structure 302, and a gate interconnect 722 extending from the second side of the fin structure 302 to the gate structure 606. An ILD layer 602 may be laterally adjacent to the gate structure 606 and may be in contact with the gate structure 606, and an ILD layer 714 laterally adjacent to the source/drain region 716 may be in contact with the source/drain region 716.

As indicated above, FIGS. 1, 2A, 2B, 3, 4A, 4B, 5, 6A-6C, and 7A-7I are provided as examples. Other examples may differ from what is described with regard to FIGS. 1, 2A, 2B, 3, 4A, 4B, 5, 6A-6C, and/or 7A-7I.

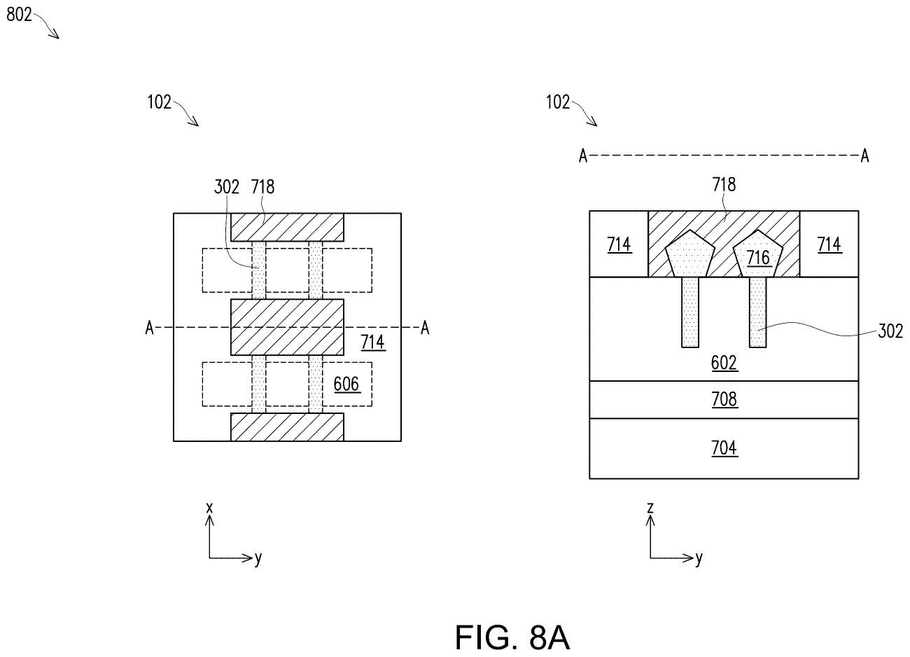

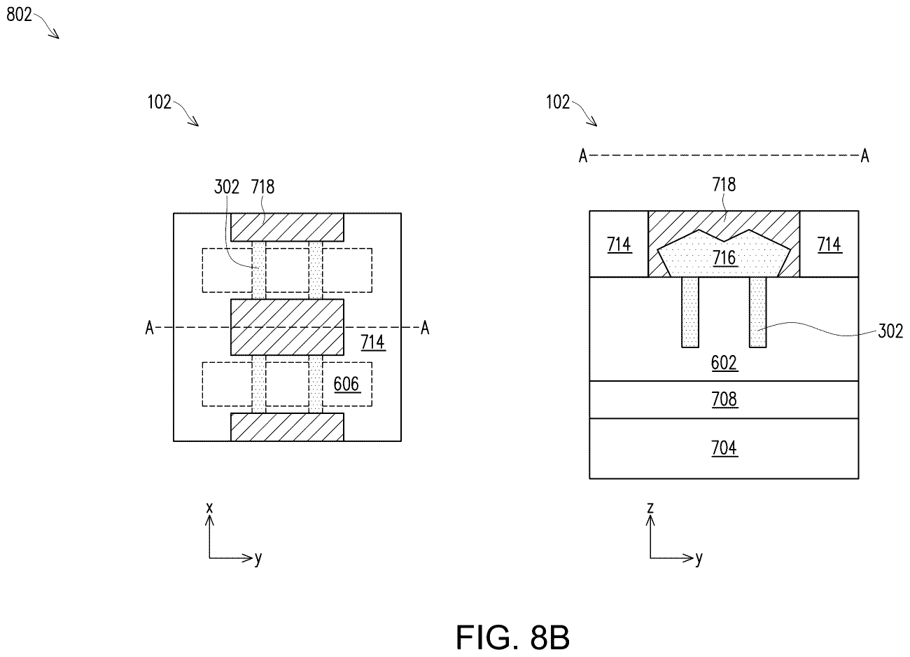

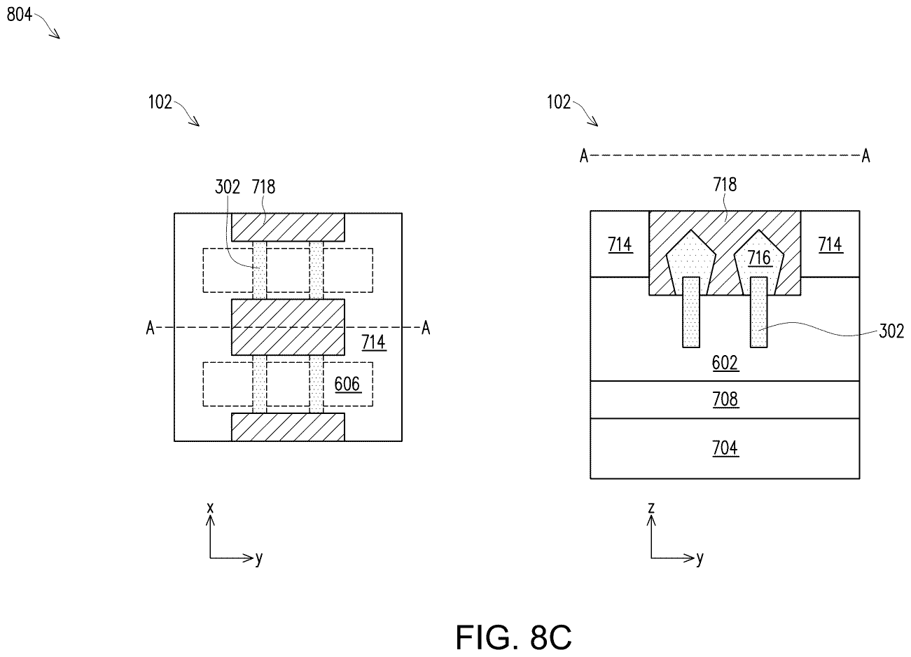

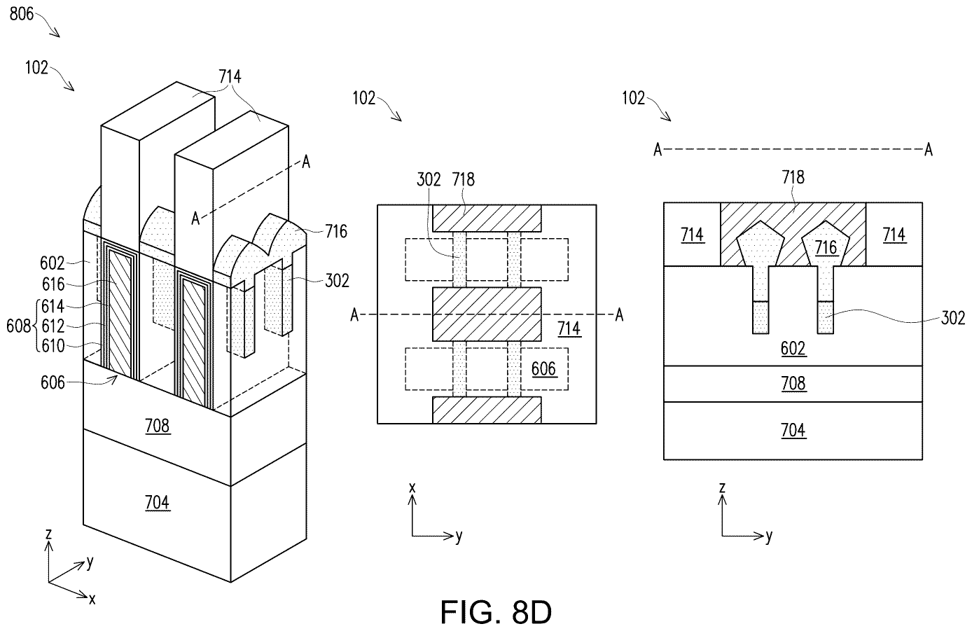

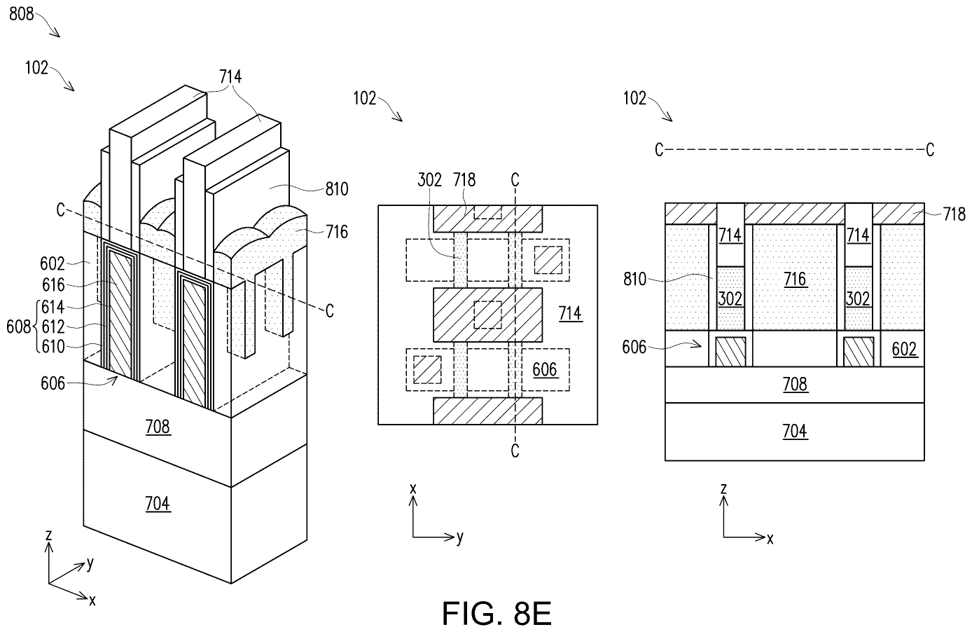

FIGS. 8A-8E are diagrams of example implementations of source/drain region arrangements for the semiconductor device 102 described herein.

As shown in an example implementation 800 in FIG. 8A, non-merged source/drain regions 716 may be formed on adjacent fin structures 302 such that the non-merged source/drain regions 716 are spaced apart and not in physical contact with each other.

As shown in an example implementation 802 in FIG. 8B, a merged source/drain region 716 may be formed on a plurality of fin structures 302 such that the merged source/drain region 716 spans across the plurality of fin structures 302. The merged source/drain region 716 may be formed by epitaxially growing source/drain regions 716 on the plurality of fin structures 302 until the source/drain regions 716 merge to form the merged source/drain region 716.

As shown in an example implementation 804 in FIG. 8C, the bottom of the ILD layer 602 around one or more fin structures 302 may be recessed by etching the ILD layer 602 from the back side of the semiconductor device 102 (e.g., during the operation described in connection with FIG. 7F). This enables a source/drain region 716 to wrap around portions of the sidewalls of a fin structure 302 in the y-direction. Moreover, a source/drain contact 718 formed on the source/drain region 716 may extend below the bottom of the ILD layer 714.

As shown in an example implementation 806 in FIG. 8D, the bottoms of one or more fin structures 302 may be recessed by etching the bottoms of the one or more fin structures 302 from the back side of the semiconductor device 102 (e.g., during the operation described in connection with FIG. 7F). This enables a source/drain region 716 to be recessed in the bottom of a fin structure 302. The source/drain region 716 may extend alongside a portion of a laterally adjacent gate structure 606.

As shown in an example implementation 808 in FIG. 8E, one or more fin structures 302 may be fully etched through along sides of one or more gate structures 606. This enables a source/drain region 716 to be recessed in the ILD layer 602 and to fully extend along a full height of a fin structure 302. The source/drain region 716 may extend alongside a portion of a laterally adjacent gate structure 606.

A fin structure 302 may be fully etched through along sides of one or more gate structures 606 by forming sidewall spacers 810 on the sidewalls of the ILD layer 714, and etching through the fin structure 302 while the sidewall spacers 810 protect the ILD layer 714 from being etched. A source/drain region 716 may be formed in the recess that was formed by fully etching through the fin structure 302, and a portion of the source/drain region 716 laterally adjacent to the ILD layer 714 may be in contact with a sidewall spacer 810.

As indicated above, FIGS. 8A-8E are provided as examples. Other examples may differ from what is described with regard to FIGS. 8A-8E.

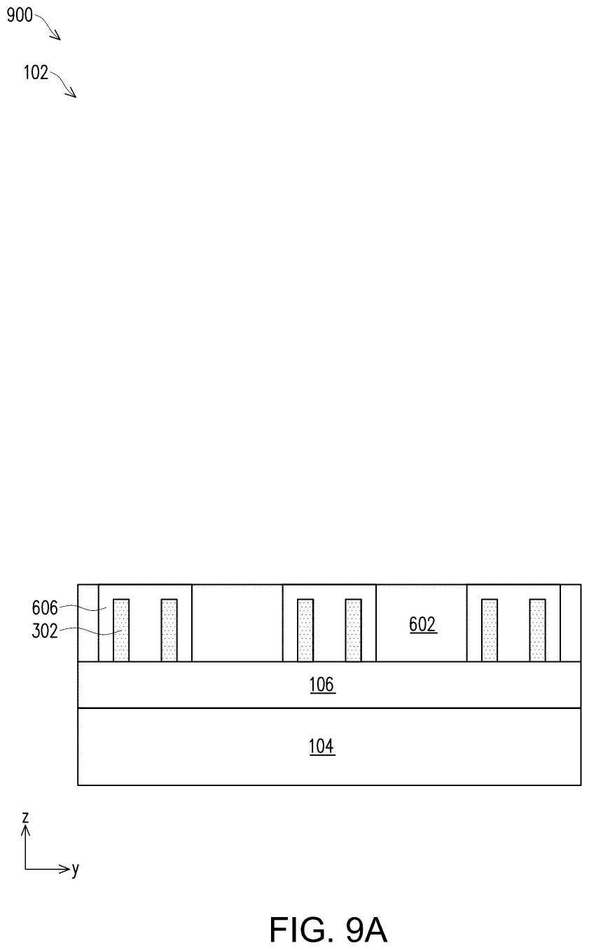

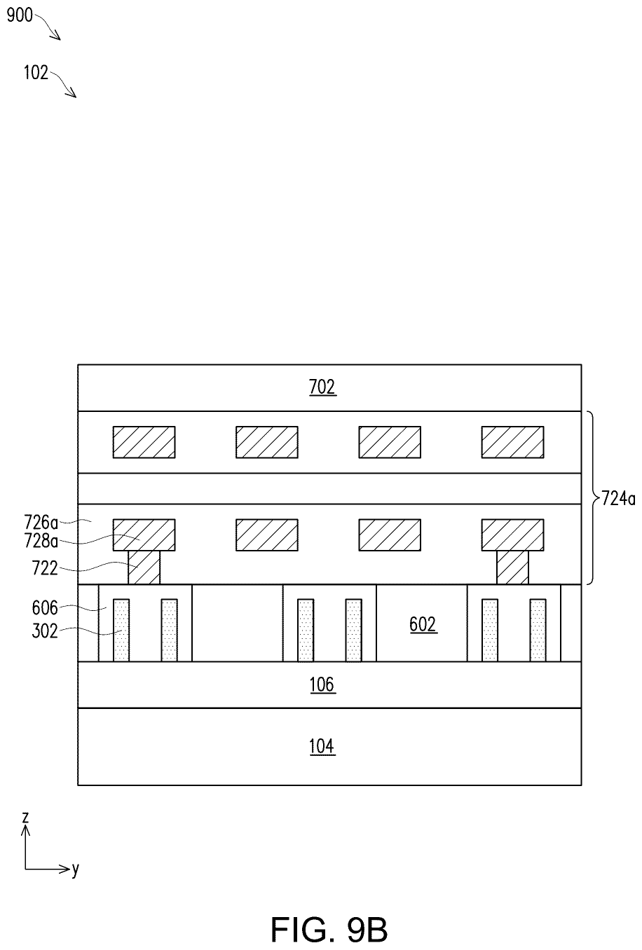

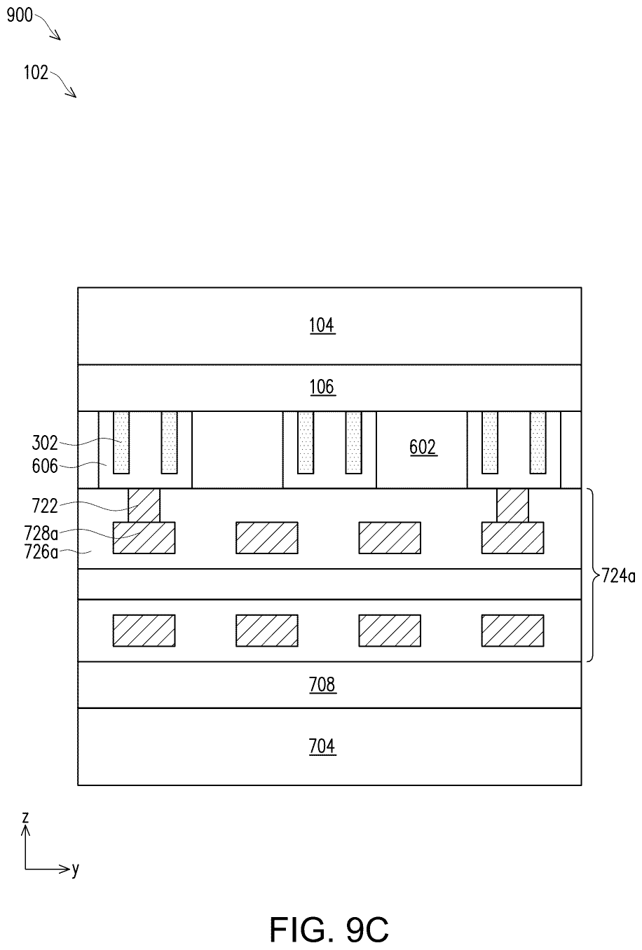

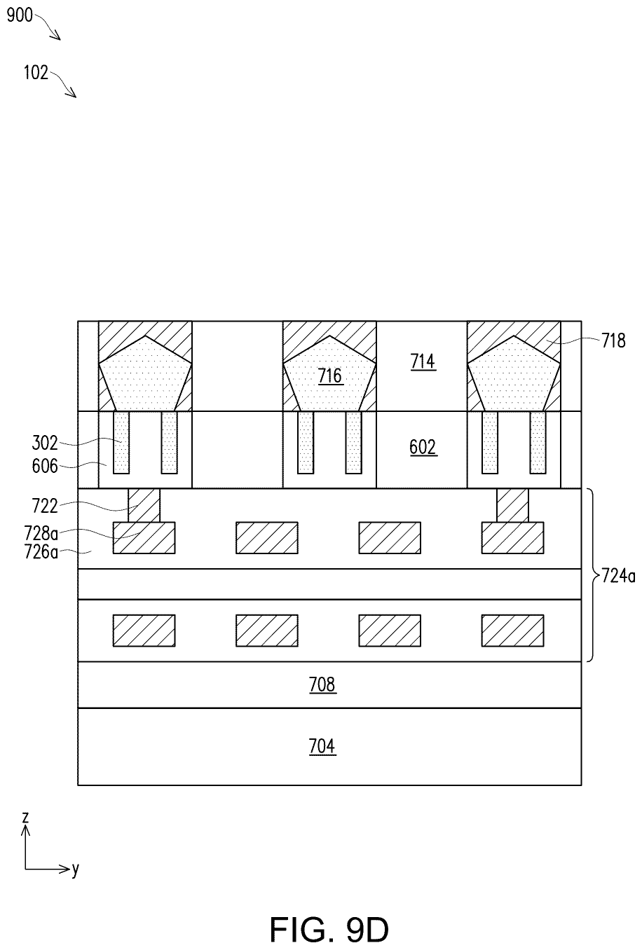

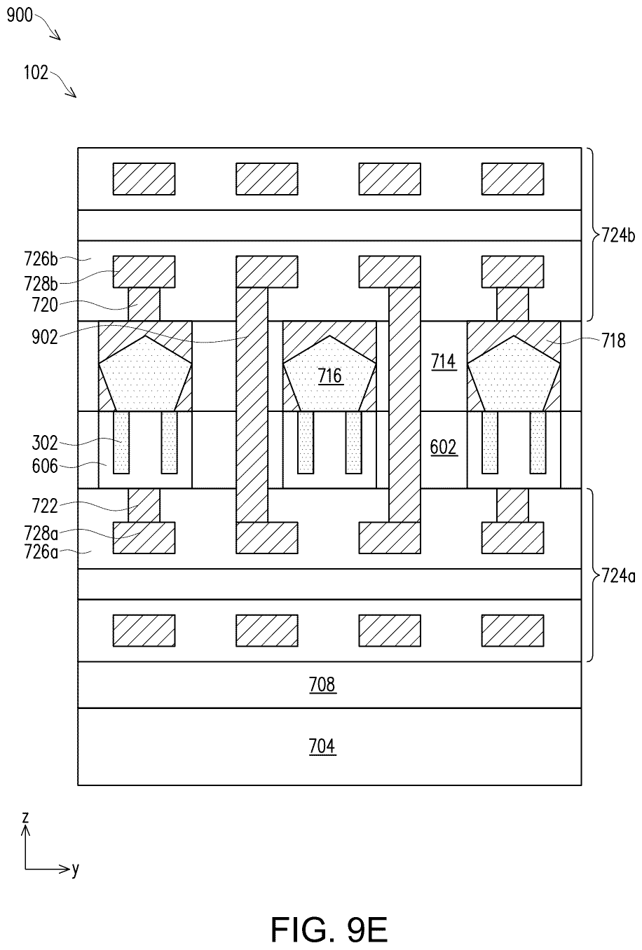

FIGS. 9A-9E are diagrams of an example implementation 900 of forming the semiconductor device 102 described herein. The example implementation 900 may include similar processes as described in connection with FIGS. 1, 2A, 2B, 3, 4A, 4B, 5, 6A-6C, and/or 7A-7I. However, in the example implementation 900, interconnect layers (e.g., BEOL regions) are formed on the front side of the semiconductor device 102 as well as on the back side of the semiconductor device 102. The interconnect layers on the front side and on the back side of the semiconductor device 102 enable signals and/or power to be distributed on both sides of the semiconductor device 102, thereby providing increased interconnect layout flexibility.

As shown in FIG. 9A, the fin structures 302, the gate structures 606, and the ILD layer 602 may be formed on the front side of the semiconductor device 102.

As shown in FIG. 9B, an interconnect layer 724a (e.g., a front side interconnect layer) may be formed on the front side of the semiconductor device 102 such that the interconnect layer 724a is located above the tops of the fin structures 302 and above the gate structures 606. The interconnect layer 724a may be formed in a similar manner as described in connection with FIG. 7I, and may include an ILD layer 726a and conductive structures 728a. Moreover, gate interconnects 722 may be formed in the interconnect layer 724a such that the gate interconnects 722 electrically connect one or more gate structures 606 to the conductive structures 728a of the interconnect layer 724a.

As shown in FIG. 9C, the semiconductor device 102 is flipped and bonded to the carrier substrate 704 using the bonding layer 708.

As shown in FIG. 9D, back side processing is performed on the semiconductor device 102 after the interconnect layer 724a is formed over the front side of the semiconductor device 102. The back side processing includes forming the ILD layer 714, forming the source/drain regions 716, and forming the source/drain contacts 718 on the back side of the semiconductor device 102.

As shown in FIG. 9E, the back side processing may include forming an interconnect layer 724b (e.g., a back side interconnect layer) on the back side of the semiconductor device 102 such that the interconnect layer 724b is located above the source/drain regions 716 and above the source/drain contacts 718. The interconnect layer 724b may be formed in a similar manner as described in connection with FIG. 7I, and may include an ILD layer 726b and conductive structures 728b. Moreover, source/drain interconnects 720 may be formed in the interconnect layer 724b such that the source/drain interconnects 720 electrically connect one or more source/drain contacts 718 to the conductive structures 728b of the interconnect layer 724b.

As further shown in FIG. 9E, through-insulator interconnect structures 902 may be formed from the back side of the semiconductor device 102 such that the through-insulator interconnect structures 902 extend through the ILD layer 714, through the ILD layer 602, and into the ILD layer 726a to a conductive structure 728a in the interconnect layer 724a. A conductive structure 728b of the interconnect layer 724b may be formed on a through-insulator interconnect structure 902 such that the through-insulator interconnect structure 902 electrically connects the interconnect layers 724a and 724b. In some implementations, a through-insulator interconnect structure 902 may extend alongside a source/drain region 716 in the z-direction in the semiconductor device. In some implementations, a through-insulator interconnect structure 902 may extend alongside a fin structure 302 in the z-direction in the semiconductor device. In some implementations, a through-insulator interconnect structure 902 may extend alongside a gate structure 606 in the z-direction in the semiconductor device.

In this way, the semiconductor device 102 may include a fin structure 302, a gate structure 606 on a first side of the fin structure 302, a source/drain region 716 on a second side of the fin structure 302 vertically opposing the first side, a source/drain contact 718 on the source/drain region 716 above the second side of the fin structure 302, a source/drain interconnect 720 on the source/drain contact 718 above the second side of the fin structure 302, and a gate interconnect 722 above the gate structure 606. An interconnect layer 724a is included above the first side of the fin structure 302, and a conductive structure 728a in the interconnect layer 724a is electrically connected to the gate interconnect 722. An interconnect layer 724b is included above the second side of the fin structure 302, and a conductive structure 728b in the interconnect layer 724b is electrically connected to the source/drain contact 718 by a source/drain interconnect 720 in the interconnect layer 724b. A through-insulator interconnect structure 902 vertically extends between the interconnect layers 724a and 724b.

As indicated above, FIGS. 9A-9E are provided as an example. Other examples may differ from what is described with regard to FIGS. 9A-9E.

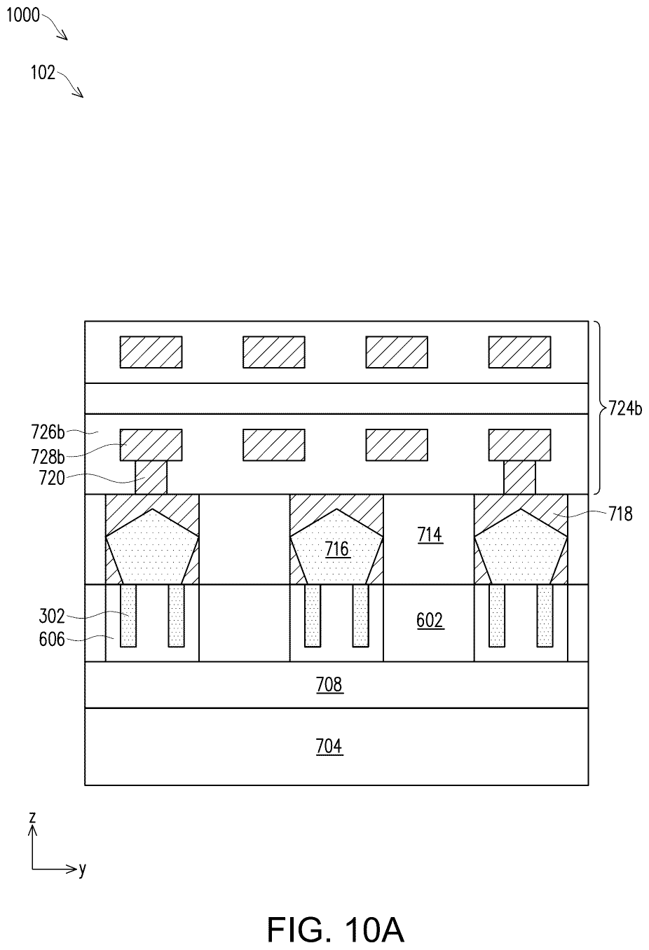

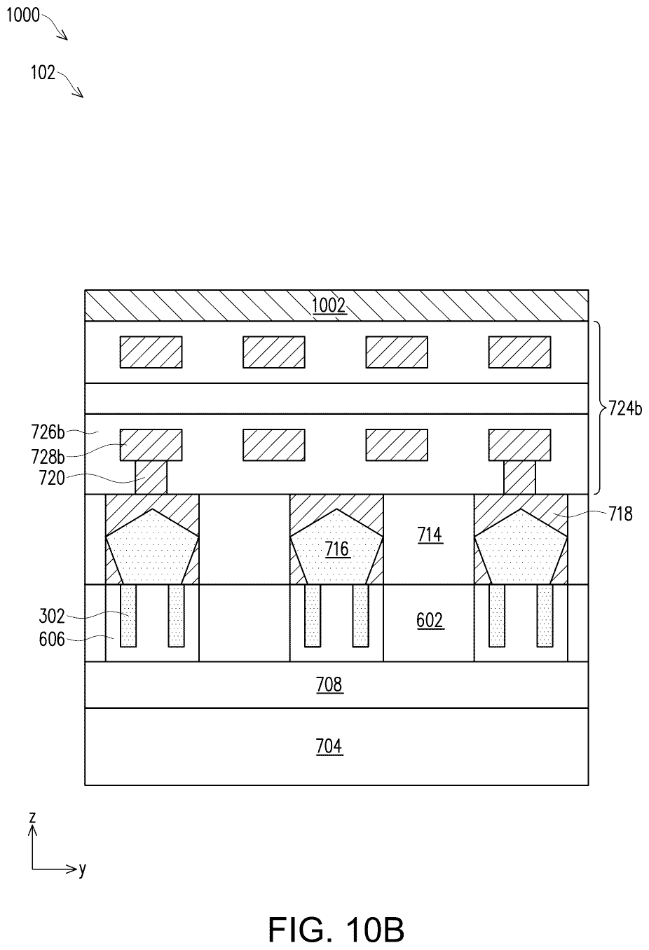

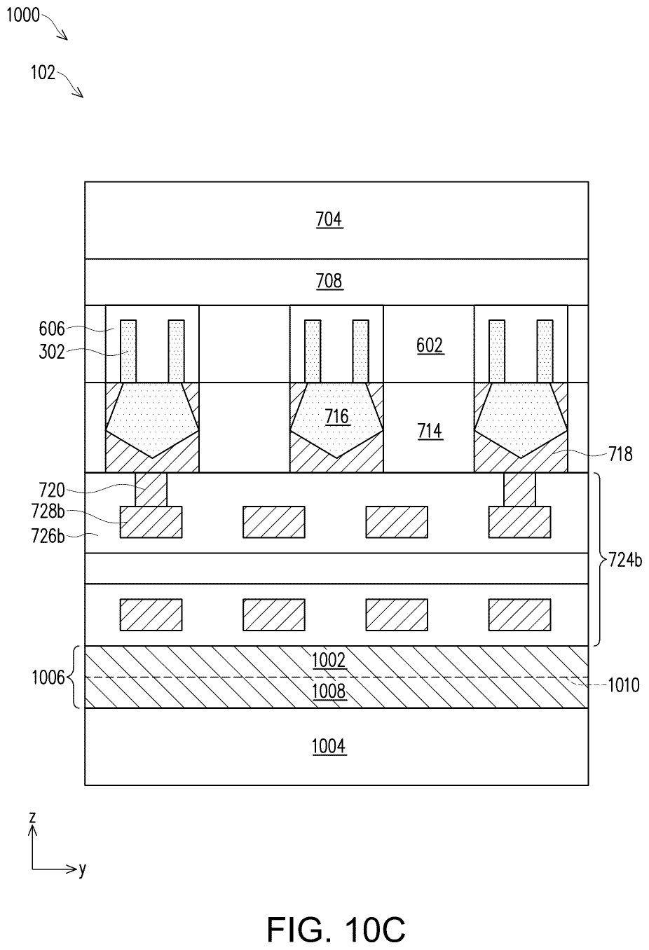

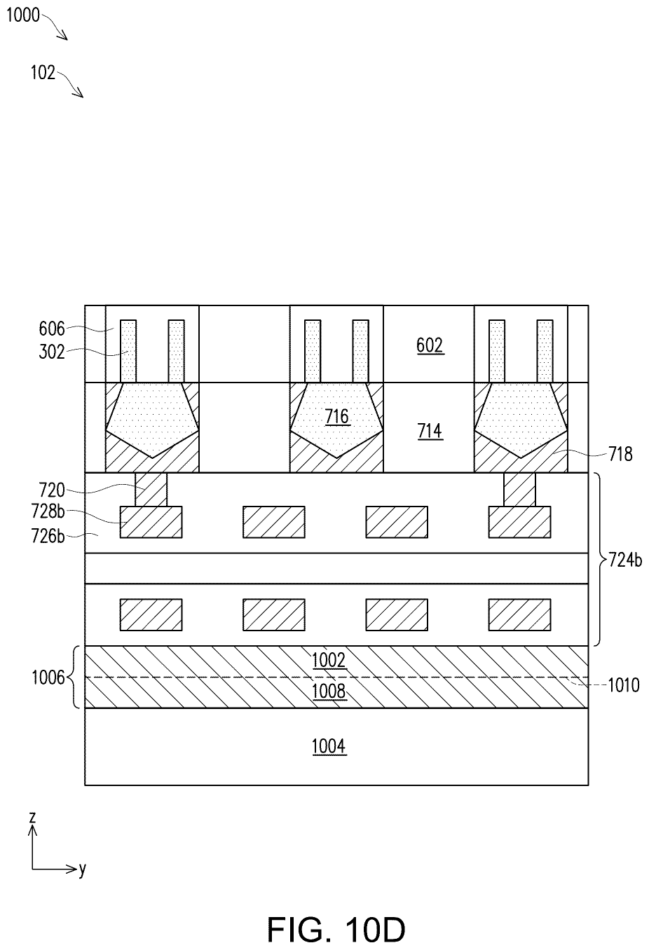

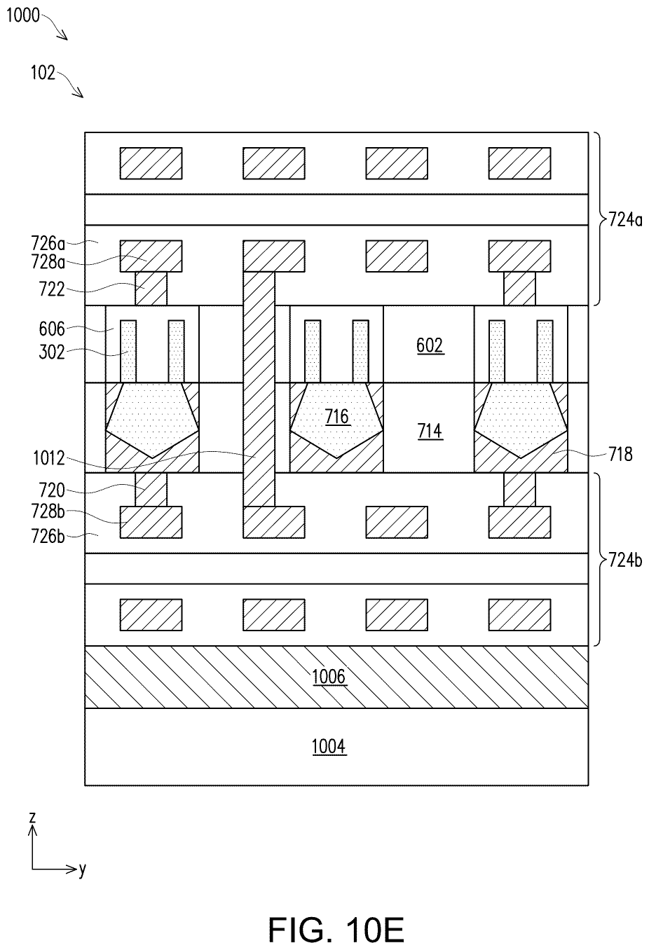

FIGS. 10A-10E are diagrams of an example implementation 1000 of forming the semiconductor device 102 described herein. The example implementation 1000 may include similar processes as described in connection with FIGS. 1, 2A, 2B, 3, 4A, 4B, 5, 6A-6C, and/or 7A-7I. However, in the example implementation 1000, interconnect layers (e.g., BEOL regions) are formed on the front side of the semiconductor device 102 as well as on the back side of the semiconductor device 102. The interconnect layers on the front side and on the back side of the semiconductor device 102 enable signals and/or power to be distributed on both sides of the semiconductor device 102, thereby providing increased interconnect layout flexibility.

As shown in FIG. 10A, the fin structures 302, the gate structures 606, and the ILD layer 602 may be formed on the front side of the semiconductor device 102. The semiconductor device 102 is flipped and bonded to the carrier substrate 704 using the bonding layer 708.

Back side processing is performed on the semiconductor device 102 after formation of the fin structures 302 and the gate structures 606 on the front side of the semiconductor device 102.

The back side processing includes forming the ILD layer 714, forming the source/drain regions 716, and forming the source/drain contacts 718 on the back side of the semiconductor device 102. Moreover, the back side processing may include forming an interconnect layer 724b (e.g., a back side interconnect layer) on the back side of the semiconductor device 102. Thus, in the example implementation 1000, the interconnect layer 724b (e.g., the back side interconnect layer) is formed prior to formation of the interconnect layer 724a (e.g., the front side interconnect layer). Source/drain interconnects 720 may be formed in the interconnect layer 724b such that the source/drain interconnects 720 electrically connect one or more source/drain contacts 718 to one or more conductive structures 728b in the interconnect layer 724b.

As shown in FIG. 10B, a bonding layer 1002 may be formed on the interconnect layer 724b on the back side of the semiconductor device 102.

As shown in FIG. 10C, the bonding layer 1002 is used to bond the back side of the semiconductor device 102 to a carrier substrate 1004. The bonding layer 1002 may be bonded to a bonding layer 1006 on the carrier substrate 1004 to form a bonding layer 1008. The bonding layer 1008 may be a merged layer that includes the bonding layers 1002 and 1006, or an interface 1010 may be visible between the bonding layers 1002 and 1006.

As shown in FIG. 10D, additional front side processing may be performed after the back side processing. The additional front side processing may include removing the carrier substrate 704 and the bonding layer 708 (e.g., in a similar manner as described in connection with FIG. 7C).

As shown in FIG. 10E, the additional front side processing includes forming the interconnect layer 724a above the front side of the semiconductor device 102. The gate interconnects 722 may be formed from the front side of the semiconductor device 102 such that the gate interconnects 722 electrically connect one or more gate structures 606 to one or more conductive structures 728a in the interconnect layer 724a.

As further shown in FIG. 10E, through-insulator interconnect structures 1012 may be formed from the front side of the semiconductor device 102 such that the through-insulator interconnect structures 1012 extend through the ILD layer 602, through the ILD layer 714, and into the ILD layer 726b to a conductive structure 728b in the interconnect layer 724b. A conductive structure 728a of the interconnect layer 724a may be formed on a through-insulator interconnect structure 1012 such that the through-insulator interconnect structure 1012 electrically connects the interconnect layers 724a and 724b. In some implementations, a through-insulator interconnect structure 1012 may extend alongside a source/drain region 716 in the z-direction in the semiconductor device. In some implementations, a through-insulator interconnect structure 1012 may extend alongside a fin structure 302 in the z-direction in the semiconductor device. In some implementations, a through-insulator interconnect structure 1012 may extend alongside a gate structure 606 in the z-direction in the semiconductor device.

In this way, the semiconductor device 102 may include a fin structure 302, a gate structure 606 on a first side of the fin structure 302, a source/drain region 716 on a second side of the fin structure 302 vertically opposing the first side, a source/drain contact 718 on the source/drain region 716 above the second side of the fin structure 302, a source/drain interconnect 720 on the source/drain contact 718 above the second side of the fin structure 302, and a gate interconnect 722 above the gate structure 606. An interconnect layer 724a is included above the first side of the fin structure 302, and a conductive structure 728a in the interconnect layer 724a is electrically connected to the gate interconnect 722. An interconnect layer 724b is included above the second side of the fin structure 302, and a conductive structure 728b in the interconnect layer 724b is electrically connected to the source/drain contact 718 by a source/drain interconnect 720 in the interconnect layer 724b. A through-insulator interconnect structure 1012 vertically extends between the interconnect layers 724a and 724b.

As indicated above, FIGS. 10A-10E are provided as an example. Other examples may differ from what is described with regard to FIGS. 10A-10E.

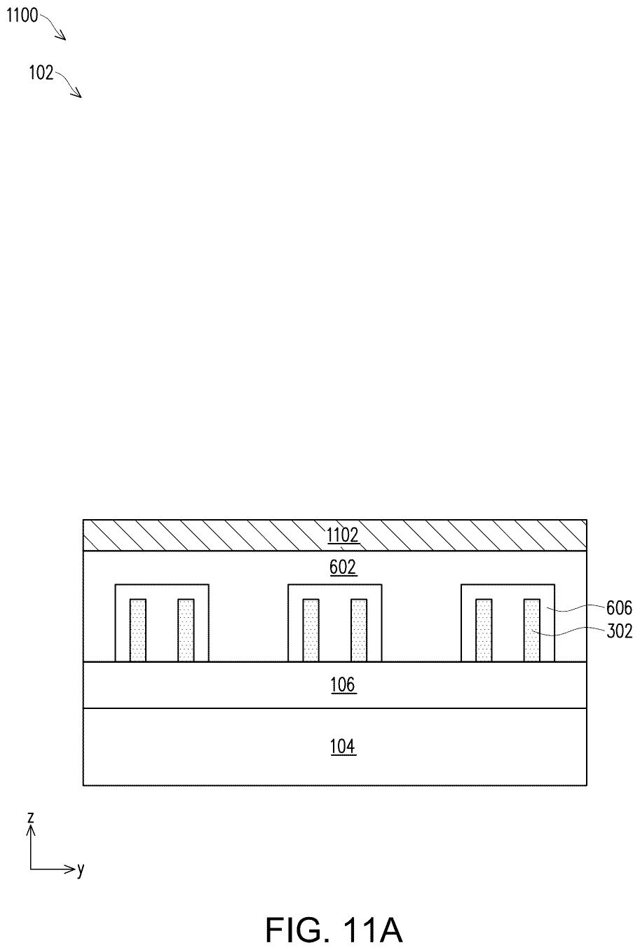

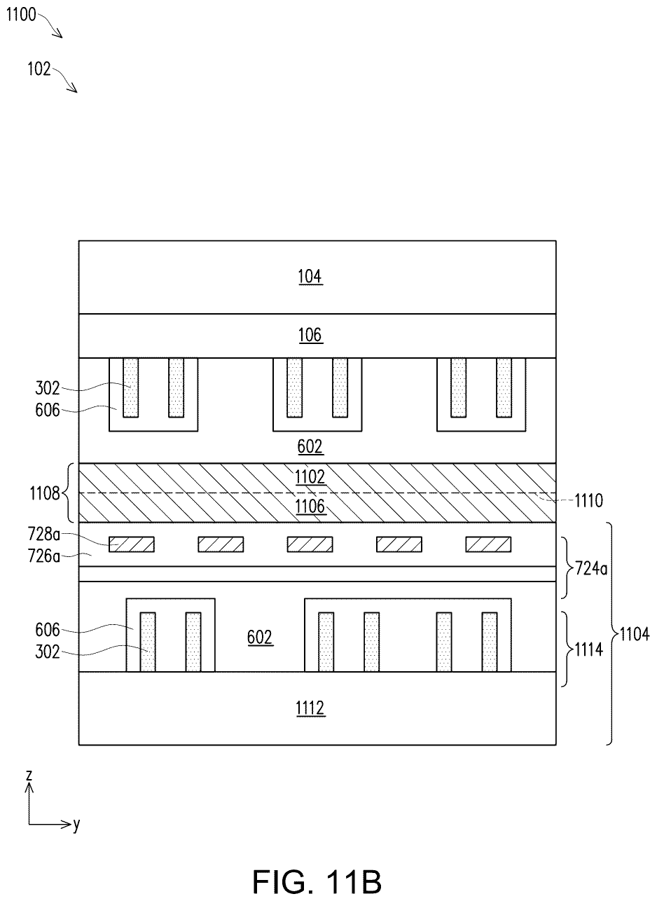

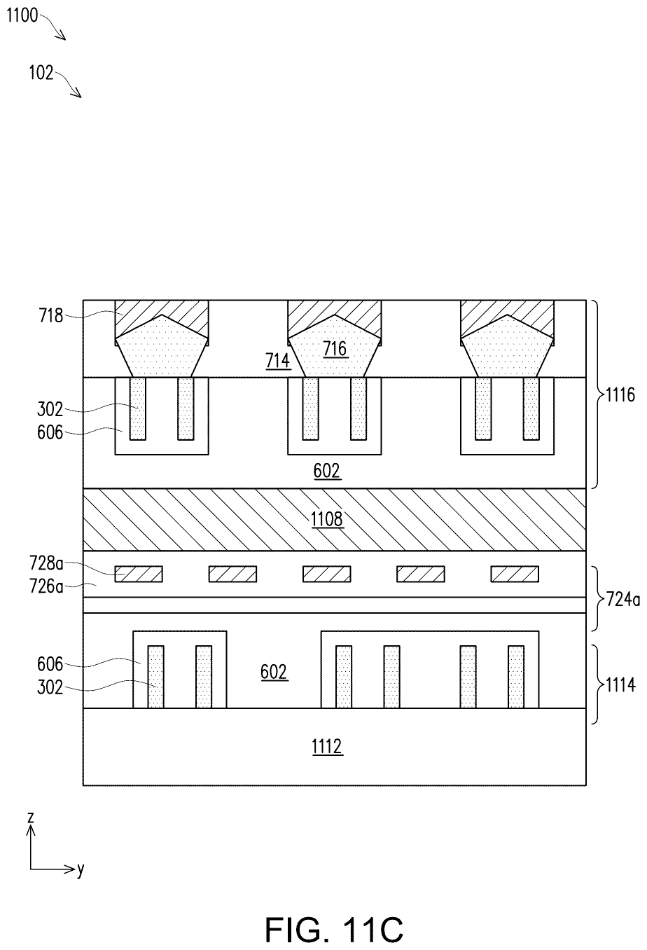

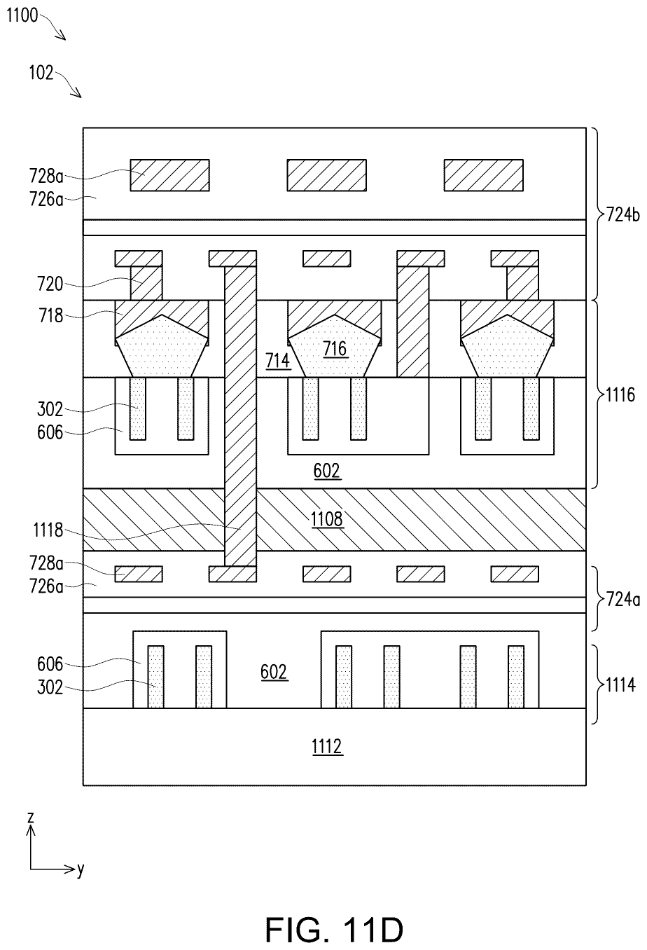

FIGS. 11A-11D are diagrams of an example implementation 1100 of forming the semiconductor device 102 described herein. The example implementation 1100 may include similar processes as described in connection with FIGS. 1, 2A, 2B, 3, 4A, 4B, 5, 6A-6C, and/or 7A-7I. However, in the example implementation 1100, the semiconductor device 102 includes a plurality of vertically-arranged (or stacked) layers of transistors that may be electrically interconnected. Arranging layers of transistors in the z-direction in the semiconductor device 102 enables the quantity of transistors in the semiconductor device 102 to be increased with minimal to no increase in a lateral footprint of the semiconductor device 102.

As shown in FIG. 11A, the fin structures 302, the gate structures 606, and the ILD layer 602 may be formed on the front side of the semiconductor device 102. A bonding layer 1102 may be formed on the ILD layer 602 above the front side of the semiconductor device 102.

As shown in FIG. 11B, the semiconductor device 102 is flipped and bonded to another semiconductor device 1104 using the bonding layer 1102. The bonding layer 1102 may be bonded to a bonding layer 1106 on the semiconductor device 1104 to form a bonding layer 1108. The bonding layer 1108 may be a merged layer that includes the bonding layers 1102 and 1106, or an interface 1110 may be visible between the bonding layers 1102 and 1106.

As shown in FIG. 11B, the semiconductor device 1104 includes a semiconductor substrate 1112, a layer of transistors 1114 above the semiconductor substrate 1112, and an interconnect layer 724a (e.g., a front side interconnect layer) above the layer of transistors 1114. The transistors in the layer of transistors 1114 may include fin structures 302, gate structures 606, source/drain regions 716 (not shown), and/or source/drain contacts 718 (not shown), among other examples.

As shown in FIG. 11C, back side processing may be performed on the semiconductor device 102 to form the ILD layer 714, the source/drain regions 716, and the source/drain contacts 718 on the back side of the semiconductor device 102. The semiconductor device 102 includes another layer of transistors 1116 above the layer of transistors 1114, and the transistors in the layer of transistors 1116 may include fin structures 302, gate structures 606, source/drain regions 716, and/or source/drain contacts 718, among other examples. The layer of transistors 1114 and the layer of transistors 1116 in the semiconductor device 102 are stacked and vertically arranged in the z-direction in the semiconductor device 102.

As shown in FIG. 11D, an interconnect layer 724b (e.g., a back side interconnect layer) may be formed above the back side of the semiconductor device 102 such that the interconnect layer 724b is located above the source/drain regions 716 and above the source/drain contacts 718 of the layer of transistors 1116. Moreover, source/drain interconnects 720 may be formed in the interconnect layer 724b such that the source/drain interconnects 720 electrically connect one or more source/drain contacts 718 to the conductive structures 728b of the interconnect layer 724b.

As further shown in FIG. 11D, through-insulator interconnect structures 1118 may be formed from the back side of the semiconductor device 102 such that the through-insulator interconnect structures 1118 extend through the layer of transistors 1116, through the bonding layer 1108, and into the ILD layer 726a to a conductive structure 728a in the interconnect layer 724a. A conductive structure 728b of the interconnect layer 724b may be formed on a through-insulator interconnect structure 1118 such that the through-insulator interconnect structure 1118 electrically connects the interconnect layers 724a and 724b. In this way, the through-insulator interconnect structure 1118 may electrically connect the layer of transistors 1114 and the layer of transistors 1116.

As indicated above, FIGS. 11A-11D are provided as an example. Other examples may differ from what is described with regard to FIGS. 11A-11D.

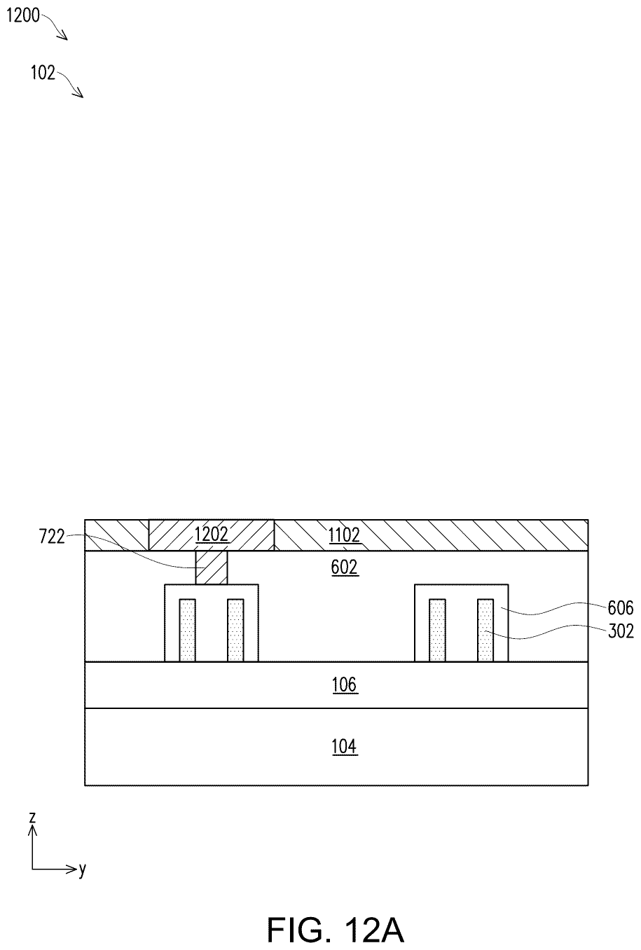

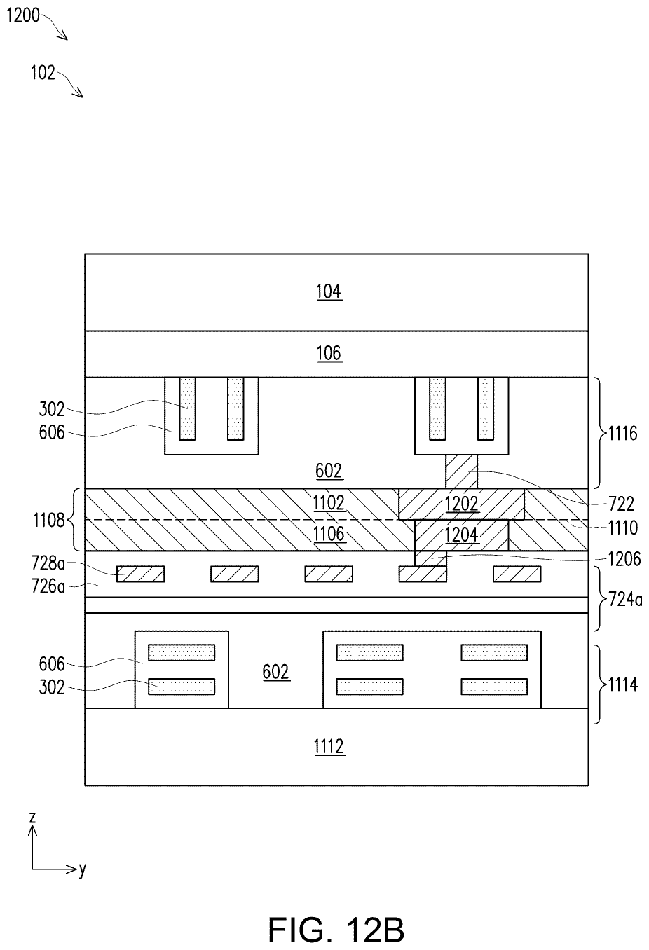

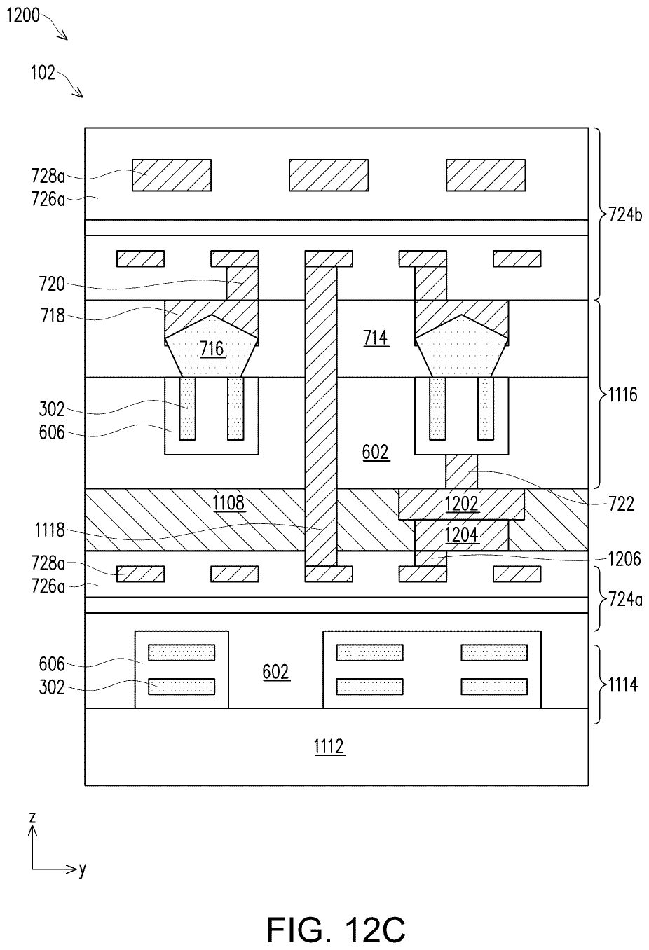

FIGS. 12A-12C are diagrams of an example implementation 1200 of forming the semiconductor device 102 described herein. The example implementation 1200 may include similar processes as described in connection with FIGS. 11A-11D. However, in the example implementation 1200, bonding structures 1202 are formed and included in the bonding layer 1102, and bonding structures 1204 are formed and included in the bonding layer 1106. The bonding structures 1204 and 1204 may include bonding vias, bonding pads, and/or other types of bonding structures. Bonding structures 1202 and 1204 include a metal, such as Cu.

As shown in FIG. 12B, the bonding structures 1204 and 1204 may be bonded together at the interface 1110 between the bonding layers 1102 and 1106. This forms a “hybrid bond”, which as a bond that includes a dielectric bond between bonding layers 1102 and 1106, and a metallic bond between bonding structures 1202 and 1204. A gate interconnect 722 in the semiconductor device 102 may electrically connect a gate structure 606 to a bonding structure 1202. Additionally and/or alternatively, a source/drain interconnect 720 in the semiconductor device 102 may electrically connect a source/drain contact 718 to a bonding structure 1202. As further shown in FIG. 12B, a conductive structure 728a in the interconnect layer 724a may be electrically connected to a bonding pad 1204 by a bonding interconnect 1206 such as a bonding via.

As shown in FIG. 12C, an interconnect layer 724b (e.g., a back side interconnect layer) may be formed above the back side of the semiconductor device 102 such that the interconnect layer 724b is located above the source/drain regions 716 and above the source/drain contacts 718 of the layer of transistors 1116. Moreover, source/drain interconnects 720 may be formed in the interconnect layer 724b such that the source/drain interconnects 720 electrically connect one or more source/drain contacts 718 to the conductive structures 728b of the interconnect layer 724b.

As further shown in FIG. 12C, through-insulator interconnect structures 1118 may be formed from the back side of the semiconductor device 102 such that the through-insulator interconnect structures 1118 extend through the layer of transistors 1116, through the bonding layer 1108, and into the ILD layer 726a to a conductive structure 728a in the interconnect layer 724a. A conductive structure 728b of the interconnect layer 724b may be formed on a through-insulator interconnect structure 1118 such that the through-insulator interconnect structure 1118 electrically connects the interconnect layers 724a and 724b. In this way, the layer of transistors 1114 and the layer of transistors 1116 may be electrically interconnected by one or more through-insulator interconnect structures 1118 and by connections between bonding structures 1202 and 1204.

As indicated above, FIGS. 12A-12C are provided as an example. Other examples may differ from what is described with regard to FIGS. 12A-12C.

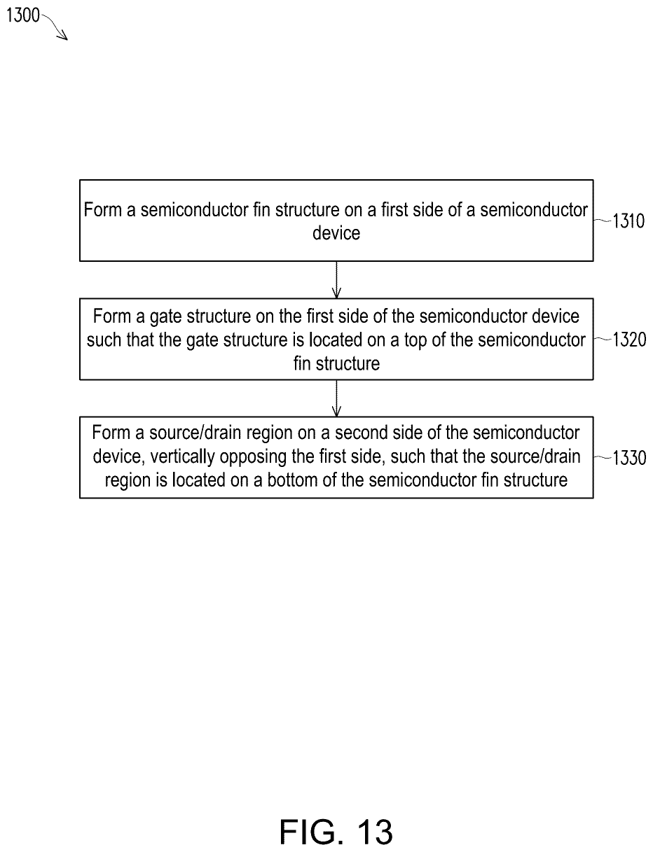

FIG. 13 is a flowchart of an example process 1300 associated with forming a semiconductor device described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming a semiconductor fin structure on a first side of a semiconductor device (block 1310). For example, one or more semiconductor processing tools may be used to form a semiconductor fin structure (e.g., a fin structure 302) on a first side of a semiconductor device (e.g., a semiconductor device 102), as described herein.

As further shown in FIG. 13, process 1300 may include forming a gate structure on the first side of the semiconductor device such that the gate structure is located on a top of the semiconductor fin structure (block 1320). For example, one or more semiconductor processing tools may be used to form a gate structure (e.g., a gate structure 606) on the first side of the semiconductor device such that the gate structure is located on a top of the semiconductor fin structure, as described herein.

As further shown in FIG. 13, process 1300 may include forming a source/drain region on a second side of the semiconductor device, vertically opposing the first side, such that the source/drain region is located on a bottom of the semiconductor fin structure (block 1330). For example, one or more semiconductor processing tools may be used to form a source/drain region (e.g., a source/drain region 716) on a second side of the semiconductor device, vertically opposing the first side, such that the source/drain region is located on a bottom of the semiconductor fin structure, as described herein.

Process 1300 may include additional implementations, such as any single implementation or any combination of implementations described below and/or in connection with one or more other processes described elsewhere herein.

In a first implementation, process 1300 includes forming a bonding layer (e.g., a bonding layer 702) on the top of the semiconductor device, and bonding the semiconductor device to a carrier substrate (e.g., a carrier substrate 704) using the bonding layer, where the gate structure and the top of the semiconductor fin structure are facing the carrier substrate.

In a second implementation, alone or in combination with the first implementation, forming the source/drain region on the second side of the semiconductor device includes forming the source/drain region on the bottom of the semiconductor fin structure after bonding the semiconductor device to the carrier substrate.

In a third implementation, alone or in combination with one or more of the first and second implementations, process 1300 includes forming an interconnect layer (e.g., an interconnect layer 724) on the second side of the semiconductor device such that the interconnect layer is located above the source/drain region.

In a fourth implementation, alone or in combination with one or more of the first through third implementations, process 1300 includes forming a source/drain contact (e.g., a source/drain contact 718) on the source/drain region, where forming the interconnect layer includes forming the interconnect layer such that the interconnect layer is located above the source/drain contact.

In a fifth implementation, alone or in combination with one or more of the first through fourth implementations, forming the interconnect layer comprises forming a source/drain interconnect (e.g., a source/drain interconnect 720) on the source/drain contact, and forming a conductive structure (e.g., a conductive structure 728) on the source/drain interconnect.

In a sixth implementation, alone or in combination with one or more of the first through fifth implementations, process 1300 includes forming a gate interconnect (e.g., a gate interconnect 722) from the second side of the semiconductor device to the gate structure, where the gate interconnect extends alongside the source/drain region.

In a seventh implementation, alone or in combination with one or more of the first through sixth implementations, forming the source/drain region includes forming the source/drain region such that the source/drain region wraps around portions of sides of the semiconductor fin structure under the gate structure.

In an eighth implementation, alone or in combination with one or more of the first through seventh implementations, forming the source/drain region includes forming a dielectric layer on the second side of the semiconductor device, forming sidewall spacers on the dielectric layer, etching through a portion of the semiconductor fin structure on a side of the gate structure to form a recess on the side of the gate structure, and forming the source/drain region in the recess.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

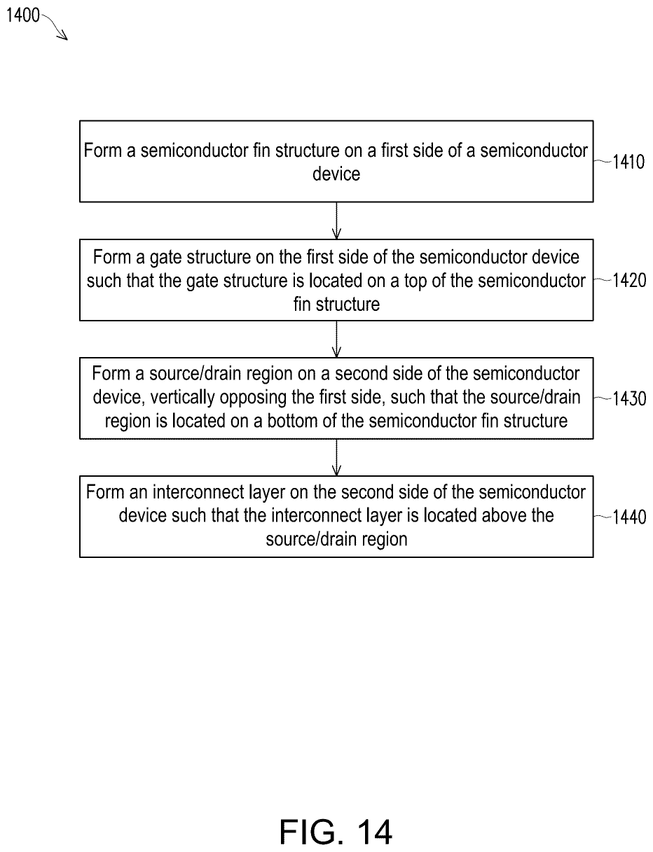

FIG. 14 is a flowchart of an example process 1400 associated with forming a semiconductor device described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming a semiconductor fin structure on a first side of a semiconductor device (block 1410). For example, one or more semiconductor processing tools may be used to form a semiconductor fin structure (e.g., a fin structure 302) on a first side of a semiconductor device (e.g., a semiconductor device 102), as described herein.

As further shown in FIG. 14, process 1400 may include forming a gate structure on the first side of the semiconductor device such that the gate structure is located on a top of the semiconductor fin structure (block 1420). For example, one or more semiconductor processing tools may be used to form a gate structure (e.g., a gate structure 606) on the first side of the semiconductor device such that the gate structure is located on a top of the semiconductor fin structure, as described herein.

As further shown in FIG. 14, process 1400 may include forming a source/drain region on a second side of the semiconductor device, vertically opposing the first side, such that the source/drain region is located on a bottom of the semiconductor fin structure (block 1430). For example, one or more semiconductor processing tools may be used to form a source/drain region (e.g., a source/drain region 716) on a second side of the semiconductor device, vertically opposing the first side, such that the source/drain region is located on a bottom of the semiconductor fin structure, as described herein.

As further shown in FIG. 14, process 1400 may include forming an interconnect layer on the second side of the semiconductor device such that the interconnect layer is located above the source/drain region (block 1440). For example, one or more semiconductor processing tools may be used to form an interconnect layer (e.g., an interconnect layer 724, an interconnect layer 724b) on the second side of the semiconductor device such that the interconnect layer is located above the source/drain region, as described herein.

Process 1400 may include additional implementations, such as any single implementation or any combination of implementations described below and/or in connection with one or more other processes described elsewhere herein.

In a first implementation, process 1400 includes forming another interconnect layer (e.g., an interconnect layer 724a) on the first side of the semiconductor device such that the other interconnect layer is located above the gate structure and the semiconductor fin structure.

In a second implementation, alone or in combination with the first implementation, forming the interconnect layer includes forming the interconnect layer prior to forming the other interconnect layer.

In a third implementation, alone or in combination with one or more of the first and second implementations, forming the other interconnect layer comprises bonding the interconnect layer to a carrier substrate (e.g., a carrier substrate 704), and forming the other interconnect layer on the second side of the semiconductor device after bonding the interconnect layer to the carrier substrate.

In a fourth implementation, alone or in combination with one or more of the first through third implementations, forming the interconnect layer includes forming the interconnect layer after forming the other interconnect layer.

In a fifth implementation, alone or in combination with one or more of the first through fourth implementations, forming the interconnect layer includes bonding the other interconnect layer to a carrier substrate (e.g., a carrier substrate 704), and forming the interconnect layer on the first side of the semiconductor device after bonding the other interconnect layer to the carrier substrate.

In a sixth implementation, alone or in combination with one or more of the first through fifth implementations, process 1400 includes bonding the semiconductor device to another semiconductor device (e.g., a semiconductor device 1104) that includes a first layer of transistor structures (e.g., a layer of transistor structures 1114) such that the gate structure and the semiconductor fin structure are facing the first layer of transistor structures, where the gate structure, the semiconductor fin structure, and the source/drain region are included in a second layer of transistor structures (e.g., a layer of transistor structures 1116) that is vertically arranged with the first layer of transistor structures.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, a fin-based transistor includes a gate structure that is vertically-arranged with source/drain regions of the fin-based transistor. The gate structure may wrap around the top and sides of a fin structure of the fin-based transistor, and source/drain regions of the fin-based transistor are located on a bottom of the fin structure. Source/drain contacts of the fin-based transistor are located on the source/drain regions over the bottom of the fin structure. This enables the gate structure and the source/drain contacts to be located on vertically opposing sides of the fin structure, thereby enabling gate spacers to be omitted from the fin-based transistor. In this way, parasitic capacitance in the fin-based transistor is reduced, and further size reductions for the fin-based transistor can be realized. Additionally and/or alternatively, vertically stacking the gate structure and the source/drain regions of the fin-based transistor enable front side and back side connections to be formed for the fin-based transistor. This enables multiple layers of fin-based transistors to be vertically stacked and interconnected to realize CMOS logic circuitry and/or to achieve greater fin-based transistor density in a semiconductor device.

As described in greater detail above, some implementations described herein provide a method. The method includes forming a semiconductor fin structure on a first side of a semiconductor device. The method includes forming a gate structure on the first side of the semiconductor device such that the gate structure is located on a top of the semiconductor fin structure. The method includes forming a source/drain region on a second side of the semiconductor device, vertically opposing the first side, such that the source/drain region is located on a bottom of the semiconductor fin structure.

As described in greater detail above, some implementations described herein provide a method. The method includes forming a semiconductor fin structure on a first side of a semiconductor device. The method includes forming a gate structure on the first side of the semiconductor device such that the gate structure is located on a top of the semiconductor fin structure. The method includes forming a source/drain region on a second side of the semiconductor device, vertically opposing the first side, such that the source/drain region is located on a bottom of the semiconductor fin structure. The method includes forming an interconnect layer on the second side of the semiconductor device such that the interconnect layer is located above the source/drain region.

As described in greater detail above, some implementations described herein provide a semiconductor device. The semiconductor device includes a semiconductor protruding structure. The semiconductor device includes a gate structure on a first side of the semiconductor protruding structure. The semiconductor device includes a source/drain region on a second side of the semiconductor fin structure vertically opposing the first side. The semiconductor device includes a first dielectric layer adjacent to the gate structure, where the first dielectric layer is in contact with the gate structure. The semiconductor device includes a second dielectric layer adjacent to the source/drain region, where the second dielectric layer is in contact with the source/drain region.

As described in greater detail above, some implementations described herein provide a semiconductor device. The semiconductor device includes a semiconductor protruding structure above a first side of the semiconductor device. The semiconductor device includes a gate structure above the first side of the semiconductor device. The gate structure is located above a top of the semiconductor protruding structure. The semiconductor device includes a source/drain region on a second side of the semiconductor device, vertically opposing the first side. The source/drain region is located above a bottom of the semiconductor protruding structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor protruding structure above a first side of the semiconductor device;
a gate structure above the first side of the semiconductor device,
wherein the gate structure is located above a top of the semiconductor protruding structure; and
a source/drain region on a second side of the semiconductor device, vertically opposing the first side,
wherein the source/drain region is located above a bottom of the semiconductor protruding structure.

2. The semiconductor device of claim 1, further comprising:
an interconnect layer on the second side of the semiconductor device,
wherein the interconnect layer is located above the source/drain region.

3. The semiconductor device of claim 2, further comprising:
a source/drain contact on the source/drain region.

4. The semiconductor device of claim 3, wherein the interconnect layer is located above the source/drain contact.

5. The semiconductor device of claim 3, wherein the interconnect layer comprises:
a source/drain interconnect on the source/drain contact; and
a conductive structure on the source/drain interconnect.

6. The semiconductor device of claim 1, further comprising:
a gate interconnect extending from the second side of the semiconductor device to the gate structure.

7. The semiconductor device of claim 6, wherein the gate interconnect extends alongside the source/drain region.

8. The semiconductor device of claim 1, wherein the source/drain region wraps around portions of sides of the semiconductor protruding structure under the gate structure.

9. A method, comprising:
forming a semiconductor fin structure on a first side of a semiconductor device;
forming a gate structure on the first side of the semiconductor device such that the gate structure is located on a top of the semiconductor fin structure;
forming a source/drain region on a second side of the semiconductor device, vertically opposing the first side, such that the source/drain region is located on a bottom of the semiconductor fin structure; and
forming an interconnect layer on the second side of the semiconductor device such that the interconnect layer is located above the source/drain region.

10. The method of claim 9, wherein forming the source/drain region comprises:
forming a dielectric layer on the second side of the semiconductor device;
forming sidewall spacers on the dielectric layer;
etching through a portion of the semiconductor fin structure on a side of the gate structure to form a recess on the side of the gate structure; and
forming the source/drain region in the recess.

11. The method of claim 10, further comprising:
forming another interconnect layer on the first side of the semiconductor device such that the other interconnect layer is located above the gate structure and the semiconductor fin structure.

12. The method of claim 11, wherein forming the interconnect layer comprises:
forming the interconnect layer prior to forming the other interconnect layer.

13. The method of claim 12, wherein forming the other interconnect layer comprises:
bonding the interconnect layer to a carrier substrate; and
forming the other interconnect layer on the second side of the semiconductor device after bonding the interconnect layer to the carrier substrate.

14. The method of claim 11, wherein forming the interconnect layer comprises:
forming the interconnect layer after forming the other interconnect layer.

15. The method of claim 14, wherein forming the interconnect layer comprises:
bonding the other interconnect layer to a carrier substrate; and
forming the interconnect layer on the first side of the semiconductor device after bonding the other interconnect layer to the carrier substrate.

16. The method of claim 11, further comprising:
bonding the semiconductor device to another semiconductor device that includes a first layer of transistor structures such that the gate structure and the semiconductor fin structure are facing the first layer of transistor structures,
wherein the gate structure, the semiconductor fin structure, and the source/drain region are included in a second layer of transistor structures that is vertically arranged with the first layer of transistor structures.

17. A semiconductor device, comprising:
a semiconductor protruding structure;
a gate structure on a first side of the semiconductor protruding structure;
a source/drain region on a second side of the semiconductor protruding structure vertically opposing the first side;
a first dielectric layer adjacent to the gate structure,
wherein the first dielectric layer is in contact with the gate structure; and
a second dielectric layer adjacent to the source/drain region,
wherein the second dielectric layer is in contact with the source/drain region.

18. The semiconductor device of claim 17, further comprising:
another semiconductor protruding structure; and
another source/drain region laterally adjacent to the source/drain region,
wherein the other source/drain region is on the other semiconductor protruding structure.

19. The semiconductor device of claim 17, further comprising:
another semiconductor protruding structure,
wherein the source/drain region is included on the other semiconductor protruding structure and spans the semiconductor protruding structure and the other semiconductor protruding structure.

20. The semiconductor device of claim 17, wherein the source/drain region is recessed in the second side of the semiconductor protruding structure.
